(19) United States
(12) Patent Application Publication
(10) Pub. No.: US 2025/0159911 A1
(43) Pub. Date: May 15, 2025

(54) MEMORY DEVICE INCLUDING A PLURALITY OF DIES

(71) Applicant: SAMSUNG ELECTRONICS CO., LTD., Suwon-si (KR)

(72) Inventors: YOSEOP LIM, Suwon-si (KR); KI-OK KIM, Suwon-si (KR); DONGKWAN HAN, Suwon-si (KR)

(73) Assignee: SAMSUNG ELECTRONICS CO., LTD., Suwon-si (KR)

(21) Appl. No.: 18/827,024

(22) Filed: Sep. 6, 2024

(30) Foreign Application Priority Data
Nov. 9, 2023 (KR) 10-2023-0154817

(51) Int. Cl. H10B 80/00; H01L 21/66; H01L 25/065

(52) U.S. Cl. CPC H10B 80/00; H01L 22/34; H01L 25/0657; H01L 2225/06513; H01L 2225/06541; H01L 2225/06596

(57) ABSTRACT

A memory device is provided. The memory device includes: a first die; a second die electrically connected to the first die; a plurality of interconnections forming a signal transmission path between the first die and the second die; a plurality of flip-flops provided in the first die that are electrically connected to the plurality of interconnections; and a test circuit provided in the second die and electrically connected to the plurality of interconnections. The test circuit is configured to perform a test operation on the plurality of interconnections using the plurality of flip-flops.

### CROSS-REFERENCE TO RELATED APPLICATION(S)

This application claims priority to Korean Patent Application No. 10-2023-0154817, filed on Nov. 9, 2023, in the Korean Intellectual Property Office, the disclosure of which is incorporated by reference herein in its entirety.

### BACKGROUND

The present disclosure relates to a memory device, and more particularly, to a memory device including a plurality of dies.

Memory devices are used to store data and may be classified as volatile and nonvolatile memory devices. A flash memory device, a type of nonvolatile memory device, may be used in a mobile phone, a digital camera, a mobile computing device, a stationary computing devices, or other devices.

As information and communication devices become more multifunctional, there is increasing demand for memory devices with a variety of performance characteristics. Accordingly, the demand for memory devices including different dies is increasing. In this case, interconnections may be formed to electrically connect the different dies. When a defect occurs in such an interconnect, it may have a significant impact on the performance of the entire memory device.

### SUMMARY

Example embodiments provide a memory device that is capable of effectively detecting a defective interconnect, among interconnects forming a signal transmission path between different dies.

According to an aspect of an example embodiment, a memory device includes: a first die; a second die electrically connected to the first die; a plurality of interconnections forming a signal transmission path between the first die and the second die; a plurality of flip-flops provided in the first die that are electrically connected to the plurality of interconnections; and a test circuit provided in the second die and electrically connected to the plurality of interconnections. The test circuit is configured to perform a test operation on the plurality of interconnections using the plurality of flip-flops.

According to an aspect of an example embodiment, a memory device includes: a first die; a second die; a plurality of through-silicon vias extending through the second die and forming a signal transmission path to the first die; a plurality of flip-flops provided in the first due that are electrically connected to the plurality of through-silicon vias; and a test circuit provided in the second die and electrically connected to the plurality of through-silicon vias. The test circuit is configured to detect whether the plurality of through-silicon vias are defective, using the plurality of flip-flops.

According to an aspect of an example embodiment, a memory device includes: an interposer; a first die on the interposer; a second die on the interposer and spaced apart from the first die along a horizontal direction; a plurality of interconnections in the interposer forming a signal transmission path between the first die and the second die; a plurality of flip-flops in the first die electrically connected to the plurality of interconnections; and a test circuit in the second die electrically connected to the plurality of interconnections. The test circuit is configured to detect whether plurality of interconnections are defective, using the plurality of flip-flops.

### BRIEF DESCRIPTION OF DRAWINGS

The above and other aspects, features, and advantages of the present disclosure will be more clearly understood from the following detailed description, taken in conjunction with the accompanying drawings.

FIG. 1 is a diagram illustrating a memory device according to an example embodiment.

FIG. 2 is a block diagram illustrating a memory device according to an example embodiment.

FIGS. 3A, 3B, 3C and 3D are diagrams illustrating examples of a test operation of the memory device of FIG. 2.

FIG. 4 is a block diagram illustrating a memory device according to an example embodiment.

FIG. 5A is a diagram illustrating an example of an operation of the memory device of FIG. 4 in a test mode, and FIG. 5B is a diagram illustrating an example of an operation of the memory device of FIG. 4 in a normal mode.

FIG. 6 is a block diagram illustrating a memory device according to an example embodiment.

FIGS. 7A, 7B and 7C are diagrams illustrating a repair operation of the memory device of FIG. 6.

FIG. 8 is a block diagram illustrating a memory device according to an example embodiment.

FIGS. 9A, 9B and 9C are diagrams illustrating an operation of the memory device of FIG. 8.

FIG. 10 is a block diagram illustrating a memory device according to an example embodiment.

FIG. 11 is a diagram illustrating conditions for identifying a defective through-silicon via, among second to eighth through-silicon vias.

FIG. 12 is a block diagram illustrating a memory device according to an example embodiment.

FIG. 13 is a diagram illustrating conditions for identifying a defective through-silicon via, among second to eighth through-silicon vias.

FIG. 14 is a block diagram illustrating a memory device according to an example embodiment.

FIG. 15 is a block diagram illustrating a memory device according to an example embodiment.

FIG. 16 is a block diagram illustrating a memory device according to an example embodiment.

FIG. 17 is a block diagram illustrating a memory device according to an example embodiment.

### DETAILED DESCRIPTION

Hereinafter, example embodiments will be described with reference to the accompanying drawings. Like components are denoted by like reference numerals throughout the specification, and repeated descriptions thereof are omitted. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Embodiments described herein are example embodiments, and thus, the present disclosure is not limited thereto, and may be realized in various other forms. Each example embodiment provided in the following description is not excluded from being associated with one or more features of another example or another example embodiment also provided herein or not provided herein but consistent with the present disclosure.

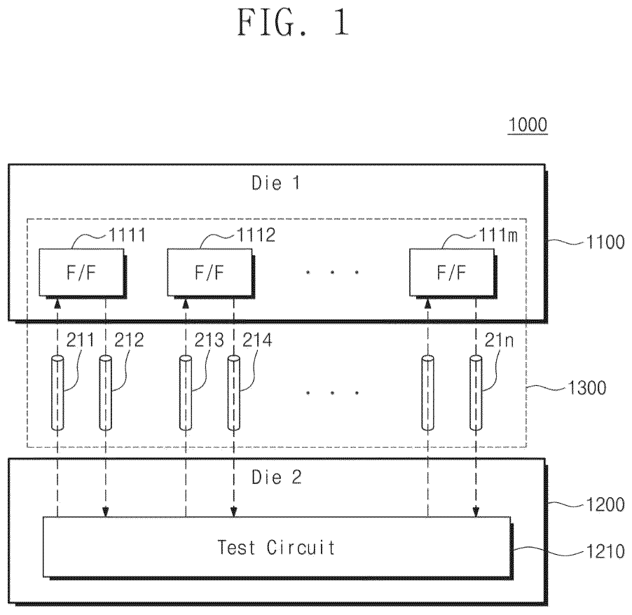

FIG. 1 is a diagram illustrating a memory device 1000 according to an example embodiment.

The memory device 1000 may include interconnections electrically connecting different dies to each other, and may detect whether one or more of the interconnections are defective. In this case, the memory device 1000 may constitute a virtual memory circuit and may detect whether one or more of the interconnections are defective through a test operation performed on the virtual memory circuit. Accordingly, the memory device 1000 may effectively detect whether the interconnection is defective, without any overhead.

A detail description will be provided with reference to FIG. 1. The memory device 1000 may include a first die 1100, a second die 1200, and interconnections 211 to 21n.

At least one semiconductor device may be disposed on each of the first die 1100 and the second die 1200. For example, a flash memory, a dynamic RAM (DRAM), a resistive RAM (ReRAM), a phase change RAM (PRAM), or a magnetic RAM (MRAM) and a large number of memory elements may be disposed on the first die 1100, and circuit elements such as a decoder and a control logic may be disposed on the second die 1200. For example, photoelectric conversion elements such as a photodiode may be disposed on the first die 1100, and circuit elements such as an analog-to-digital converter (ADC) may be disposed on the second die 1200. However, this is only an example, and the semiconductor elements disposed on the first die 1100 and the second die 1200 are not limited thereto.

The first die 1100 and the second die 1200 may be disposed in various ways, and may be electrically connected to each other. To this end, the memory device 1000 may include interconnections 211 to 21n.

In an example embodiment, the first die 1100 and the second die 1200 may be vertically stacked. For example, each of the first die 1100 and the second die 1200 may be a vertically stacked memory die of a three-dimensionally (3D) stacked memory. For example, each of the first die 1100 and the second die 1200 may be a vertically stacked system in package (SiP) logic die. For example, the first die 1100 may be a memory die, and the second die 1200 may be a logic die.

In this case, the interconnections 211 to 21n may electrically connect the vertically stacked first die 1100 and the second die 1200 to each other. For example, each of the interconnections 211 to 21n may be a through-silicon via (hereinafter referred to as a “TSV”). In this case, the through-silicon via TSV may be formed in the first die 1100, the second die 1200, or both the first die 1100 and the second die 1200. For example, each of the interconnections 211 to 21n may be a bump or a micro-bump disposed between the first die 1100 and the second die 1200. Alternatively, for example, each of the interconnections 211 to 21n may be a combination of a through-silicon via TSV and a bump, a combination of a through-silicon via TSV and a micro-bump, or a combination of a through-silicon via TSV, a bump, and a micro-bump.

In an example embodiment, the first die 1100 and the second die 1200 may be disposed in a horizontal direction. For example, the first die 1100 and the second die 1200 may be implemented as chiplets. For example, the first die 1100 may be a logic die performing a first function and the second die 1200 may be a logic die performing a second function, and the first die 1100 and the second die 1200 may be electrically connected through interconnections 211 to 21n. In this case, each of the interconnections 211 to 21n may be implemented as a through-silicon via TSV.

In an example embodiment, each of the first die 1100 and the second die 1200 may be disposed on an interposer. For example, the first die 1100 may be a memory die disposed on an interposer and the second die 1200 may be a logic die disposed on the interposer, and the first die 1100 and the second die 1200 may be electrically connected through interconnections 211 to 21n. In this case, each of the interconnections 211 to 21n may be a metal line disposed within the interposer. However, this is only an example, and each of the interconnections 211 to 21n may be a micro-bump disposed between the first die 1100 and the interposer or a micro-bump disposed between the second die 1200 and the interposer.

The memory device 1000 may perform a test operation to detect a defective interconnection, among the interconnections 211 to 21n. The memory device 1000 may constitute a virtual memory circuit 1300, including the interconnections 211 to 21n, to effectively perform a test operation on the interconnections 211 to 21n. The virtual memory circuit 1300 may operate, similarly to an internal memory of the memory device 1000, such as SRAM. Accordingly, a test operation on the internal memory may be equally applied to the virtual memory circuit 1300.

A more detailed description is now provided. For example, the first die 1100 may be implemented to include a plurality of flip-flops 1111 to 111m, as illustrated in FIG. 1. At least one interconnection may be connected to an input terminal of each flip-flop, and at least one interconnection may be connected to an output terminal of each flip-flop. The plurality of flip-flops 1111 to 111m and corresponding interconnections 211 to 21n may constitute a virtual memory circuit 1300.

Each of the plurality of flip-flops 1111 to 111m may correspond to, for example, a bit-cell of an SRAM. An interconnection, connected to an input terminal of each flip-flop, may correspond to an input port of the SRAM. An interconnection, connected to an output terminal of each flip-flop, may correspond to an output port of the SRAM. Accordingly, the plurality of flip-flops 1111 to 111m and the corresponding interconnections 211 to 21n may operate, similarly to the SRAM.

The second die 1200 may include a test circuit 1210. For example, the test circuit 1210 of the second die 1200 may be used to check whether the SRAM operates normally. For example, a test logic used in the test circuit 1210 to test the SRAM may also be used to test the virtual memory circuit 1300.

In general, when a test operation is performed on the SRAM, a write operation to input desired data to a bit-cell, a read operation to read stored data from the bit-cell, and a comparison operation to determine whether the data input to the bit-cell and the data read from the bit-cell are the same may be sequentially performed.

In a similar manner, the test circuit 1210 of the second die 1200 may perform a test operation on the virtual memory circuit 1300 through a data input operation, a data output operation, and a data comparison operation in the test mode.

For example, the test circuit 1210 of the second die 1200 may provide an input signal to each flip-flop through an interconnection, connected to an input terminal of each flip-flop, during the data input operation in the test mode. For example, the test circuit 1210 may provide an input signal to the first flip-flop 1111 through the first interconnection 211.

The test circuit 1210 of the second die 1200 may receive an output signal from each flip-flop through an interconnection, connected to an output terminal of each flip-flop, during the read operation in the test mode. For example, the test circuit 1210 may receive an output signal from the first flip-flop 1111 through the second interconnection 212.

The test circuit 1210 of the second die 1200 may compare the input signal and the output signal corresponding to each flip-flop and determine whether an interconnection is defective based on a result of the comparison, during the comparison operation in the test mode. For example, when the input signal provided to the first flip-flop 1111 through the first interconnection 211 and the output signal output from the first flip-flop 1111 through the second interconnection 212 are different from each other, the test circuit 1210 may determine that at least one of the first interconnection 211 or the second interconnection 212 is defective.

As described above, the memory device 1000 may perform a test operation on the interconnections 211 to 21n using the test logic used in a test operation for the internal memory such as an SRAM. Accordingly, an additional logic circuit is not required, so that the memory device 1000 may effectively perform a test operation on the interconnections 211 to 21n without any significant overhead.

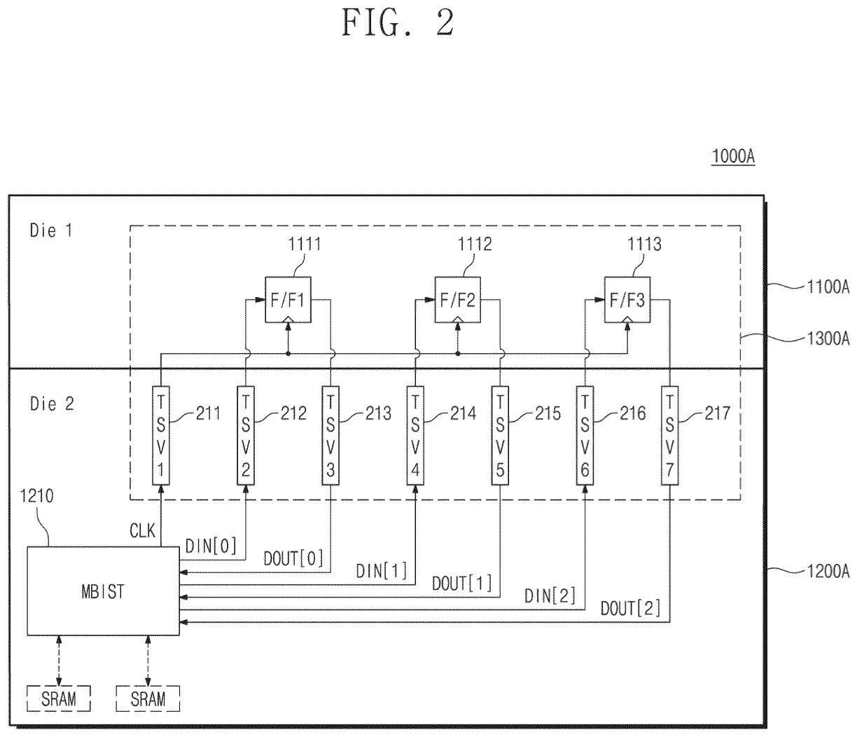

Hereinafter, various examples of a memory device, constituting a virtual memory circuit to detect whether one or more interconnections are defective, according to example embodiments will be described in more detail. For ease of description, in FIGS. 2 to 11, an example is provided in which flip-flops are formed on a first die Die1, interconnections and test circuits are formed on a second die Die2, and the first die Die1 and the second die Die2 are stacked vertically. In addition, an example is provided in which interconnections are implemented using through-silicon vias (TSVs) and test circuits are implemented using Memory Built-In Self Test (MBIST).

FIG. 2 is a block diagram illustrating a memory device 1000A according to an example embodiment. The memory device 1000A of FIG. 2 is similar to the memory device 1000 of FIG. 1. Therefore, the same or similar components will be represented by the same or similar reference numerals, and redundant descriptions will be omitted.

Referring to FIG. 2, the memory device 1000A may include a first 100A and a second 200A stacked vertically, and a virtual memory circuit 1300A may be formed across the first die 1100A and the second die 1200A.

The first die 1100A may include a plurality of flip-flops. For example, the first die 1100A may include first to third flip-flops 1111 to 1113, as illustrated in FIG. 2.

The second die 1200A may include a plurality of through-silicon vias (TSVs) and MBIST 1210. For example, the second die 1200A may be connected to first to seventh through-silicon vias TSV1 to TSV7 and the MBIST 1210 connected to the first to seventh through-silicon vias TSV1 to TSV7. According to example embodiments, the second die 1200A may further include an SRAM.

The first through-silicon via 211 may receive a clock signal CLK from the MBIST 1210. The first through-silicon via 211 may provide a clock signal CLK to the first to third flip-flops 1111 to 1113.

The second through-silicon via 212 and the third through-silicon via 213 may be electrically connected to the first flip-flop 1111.

For example, the second through-silicon via 212 may be connected to an input terminal of the first flip-flop 1111. A 0th data input signal DIN[0] from the MBIST 1210 may be provided to the first flip-flop 1111 through the second through-silicon via 212. The third through-silicon via 213 may be connected to an output terminal of the first flip-flop 1111. A 0th data output signal DOUT[0] from the first flip-flop 1111 may be provided to the MBIST 1210 through the third through-silicon via 213.

Similarly, the fourth through-silicon via 214 and the fifth through-silicon via 215 may be electrically connected to the second flip-flop 1112. The first data input signal DIN[1] may be transmitted through the fourth through-silicon via 214, and the first data output signal DOUT[1] may be transmitted through the fifth through-silicon via 215.

In addition, the sixth through-silicon via 216 and the seventh through-silicon via 217 may be electrically connected to the third flip-flop 1113. A second data input signal DIN[2] may be transmitted through the sixth through-silicon via 216, and a second data output signal DOUT[2] may be transmitted through the seventh through-silicon via 217.

The virtual memory circuit 1300A may include first to third flip-flops 1111 to 1113 and first to seventh through-silicon vias 211 to 217. The MBIST 1210 may perform a test operation on the virtual memory circuit 1300A using a test logic used in a test operation on an SRAM. Accordingly, a defective through-silicon via, among the first to seventh through-silicon vias 211 to 217, may be detected.

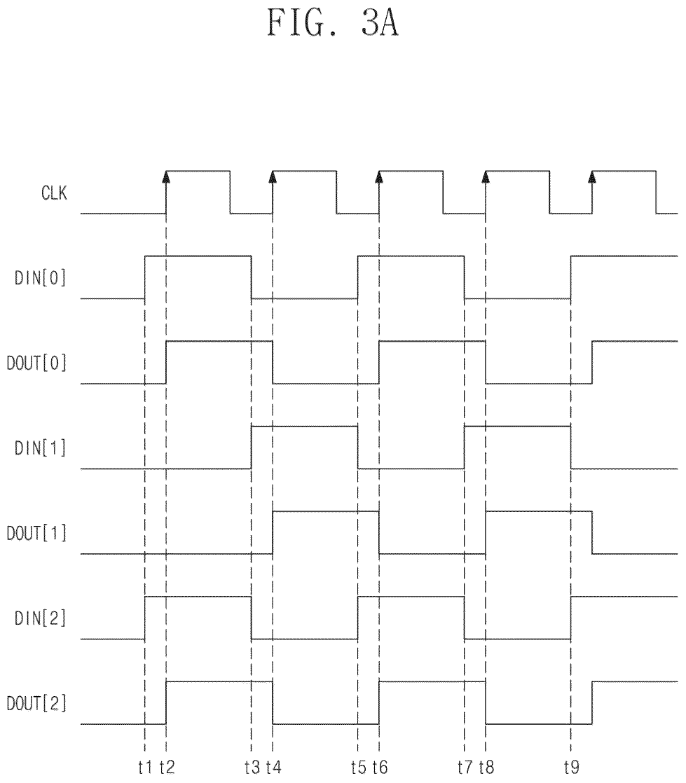

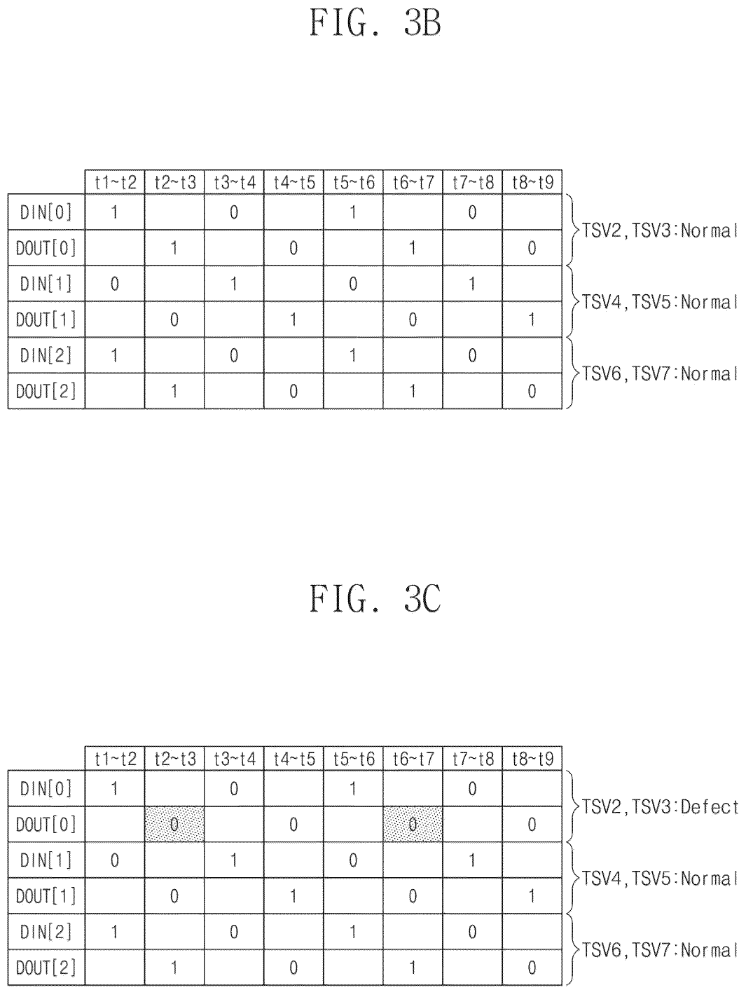

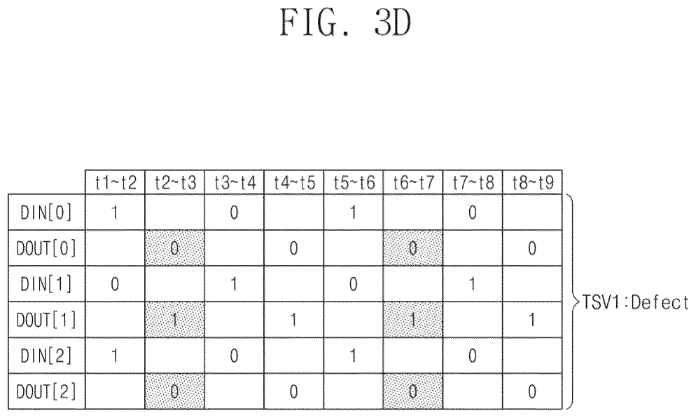

FIGS. 3A and 3B are diagrams illustrating an example of a test operation of the memory device of FIG. 2.

FIGS. 3A and 3B are diagrams illustrating an example of a test operation of the memory device 1000A of FIG. 2. Specifically, FIG. 3A is a timing diagram illustrating an example of a test operation when there is no defect in the through-silicon vias 211 to 217, and FIG. 3B is a diagram illustrating a test result when there is no defect in the through-silicon vias 211 to 217.

Referring to FIGS. 2, 3A, and 3B, a data input operation in a test mode may be performed between a first time t1 and a second time t2.

For example, a high-level 0th data input signal DIN[0] may be provided to the second through-silicon via 21 between the first time t1 and the second time point t2. The 0th data input signal DIN[0] may be provided to an input terminal of the first flip-flop 1111 via the second through-silicon via 212.

A low-level first data input signal DIN[1] may be provided to the fourth through-silicon via 214 between the first time t1 and the second time t2. The first data input signal DIN[1] may be provided to an input terminal of the second flip-flop 1112 via the fourth through-silicon via 214.

A high-level second data input signal DIN[2] may be provided to the sixth through-silicon via 216 between the first time t1 and the second time t2. The second data input signal DIN[2] may be provided to an input terminal of the third flip-flop 1113 via the sixth through-silicon via 216.

At the second time t2, the clock signal CLK may transition from a low level to a high level.

A data output operation and a data comparison operation in the test mode may be performed between the second time t2 and a third time t3.

For example, the first flip-flop 1111 may reflect a signal level at the input terminal to an output signal at the output terminal, based on a rising edge of a clock signal CLK at the second time t2. The output signal of the first flip-flop 1111 may be transmitted to the MBIST 1210 via the third through-silicon via 213 as the 0th data output signal DOUT[0] between the second time t2 and the third time t3.

When the second and third through-silicon vias 212 and 213 are normal, a signal level of the 0th data input signal DIN[0] between the first time t1 and the second time t2 may be the same as a signal level of the 0th data output signal DOUT[0] between the second time t2 and the third time t3.

When at least one of the second and third through-silicon vias 212 and 213 is defective, a signal level of the 0th data input signal DIN[0] may be distorted by the defective through-silicon via. For example, when at least one of the second and third through-silicon vias 212 and 213 is defective, a signal level of the 0th data input signal DIN[0] between the first time t1 and the second time t2 may be different from a signal level of the 0th data output signal DOUT[0] between the second time t2 and the third time points t3.

The MBIST 1210 may compare the signal level of the 0th data input signal DIN[0] between the first time t1 and the second time t2 and the signal level of the 0th data output signal DOUT[0] between the second time t2 and the third time t3, and determine whether one or both of the second and third through-silicon vias 212 and 213 are defective based on a result of the comparison.

For example, as illustrated in FIGS. 3A and 3B, when both the signal level of the 0th data input signal DIN[0] between the first time t1 and the second time t2 and the signal level of the 0th data output signals DOUT[0] between the second time t2 and the third time t3 are high, the MBIST 1210 may determine that the second and third through-silicon vias 212 and 213 are normal.

Similarly, the second flip-flop 1112 may reflect the signal level at the input terminal to the output signal at the output terminal, based on a rising edge of the clock signal CLK at the second time t2. The output signal of the second flip-flop 1112 may be transmitted to the MBIST 1210 via the fifth through-silicon via 215 as the first data output signal DOUT[1] between the second time t2 and the third time t3.

The MBIST 1210 may compare the signal level of the first data input signal DIN[1] between the first time t1 and the second time t2 and the signal level of the first data output signal DOUT[1] between the second time t2 and the third time t3, and determine whether one or both of the fourth and fifth through-silicon vias 214 and 215 are defective based on a result of the comparison. For example, as illustrated in FIGS. 3A and 3B, when both the signal level of the first data input signal DIN[1] between the first time t1 and the second time t2 and the signal level of the first data output signal DOUT[1] between the second time t2 and the third time t3 are low, the MBIST 1210 may determine that the fourth and fifth through-silicon vias 214 and 215 are normal.

Similarly, based on a rising edge of the clock signal CLK at the second time t2, the third flip-flop 1113 may reflect the signal level at the input terminal to the output signal at the output terminal, and the MBIST 1210 may determine whether one or both of the sixth and seventh through-silicon vias 216 and 217 are defective. For example, as illustrated in FIGS. 3A and 3B, when both the signal level of the second data input signal DIN[2] between the first time t1 and the second time t2 and the signal level of the second data output signals DOUT[2] between the second time t2 to the third time t3 are high, the MBIST 1210 may determine that the sixth and seventh through-silicon vias 216 and 217 are normal.

A data input operation, a data output operation, and a data comparison operation in the test mode may be repeatedly performed between the third time t3 and a fifth time t5.

For example, the data input operation in the test mode may be performed between the third time t3 and a fourth time t4. In this case, the signal level of the data input signal may be set to be different from the signal level between the first time t1 and the second time t2. At the fourth time t4, the clock signal CLK may transition from a low level to a high level. A data output operation and a data comparison operation in the test mode may be performed between the fourth time t4 and the fifth time t5.

A data input operation, a data output operation, and a data comparison operation in the test mode may be repeatedly performed between the fifth time t5 and a seventh time t7.

In addition, a data input operation, a data output operation, and a data comparison operation in the test mode may be repeatedly performed between the seventh time t7 and a ninth time t9.

As described above, when a signal level of a data input signal provided to a through-silicon via connected to an input terminal of a flip-flop is the same as a signal level of a data output signal output from a through-silicon via connected to an output terminal of the flip-flop, it may be determined that the through-silicon via is normal.

FIGS. 3C and 3D are drawings illustrating another example of the test operation of the memory device 1000A of FIG. 2. In FIG. 3C, an example is provided in which at least one of the second and third through-silicon vias 212 and 213 is defective. In FIG. 3D, an example is provided in which the first through-silicon via 211 is defective.

When a through-silicon via is defective, a signal level of a signal provided through the through-silicon via may be distorted.

For example, when a through-silicon via connected to an input terminal of a flip-flop is defective, a signal level of a data input signal provided to the defective through-silicon via may be distorted. Accordingly, the signal level of the data input signal provided to the defective through-silicon via and the signal level of the data output signal corresponding to the data input signal may be different from each other.

Similarly, when the through-silicon via connected to an output terminal of the flip-flop is defective or when both through-silicon vias connected to the input terminal and the output terminal of the flip-flop are defective, a signal level of a data input signal and a signal level of a data output signal corresponding to the data input signal may be different from each other.

A detailed description is now provided with reference to FIGS. 2 and 3C. When at least one of the second through-silicon via 212 and the third through-silicon via 213 is defective, the first data input signal DIN[0] may be distorted by the defective through-silicon via. Accordingly, a signal level of the first data input signal DIN[0] and a signal level of the first data output signal (DOUT[0]) may be different from each other.

For example, the signal level of the first data input signal DIN[0] is a high level between the first time t1 and the second time t2, but the signal level of the first data output signal DOUT[0] between the second time t2 and the third time t3 may be a low level. In addition, the signal level of the first data input signal DIN[0] between the fifth time t5 and the sixth time t6 is a high level, but the signal level of the first data output signal DOUT[0] between the sixth time t6 and the seventh time t7 may be a low level.

In this case, the MBIST 1210 may determine that at least one of the second through-silicon via 212 corresponding to the first data input signal DIN[0] and the third through-silicon via 213 corresponding to the first data output signal DOUT[0] is defective.

In addition, for example, when a through-silicon via through which a clock signal CLK passes is defective, a clock signal CLK provided to each flip-flop may be distorted. In this case, all the flip-flops do not operate normally, so that a data input signal and a corresponding data output signal may not match each other in many cases or may be generated randomly.

A detailed description is now provided with reference to FIGS. 2 and 3D. When the first through-silicon via 211 is defective, the clock signal CLK may be distorted by the defective first through-silicon via 211 and the first to third flip-flops 1111 to 1113 may operate based on the distorted clock signal. Accordingly, errors may occur in all through-silicon vias TSV2 to TSV7 corresponding to the first to third flip-flops 1111 to 1113, as illustrated in FIG. 3D. In this case, the MBIST 1210 may determine that the first through-silicon via 211 corresponding to the clock signal CLK is defective.

As described above with reference to FIGS. 2 to 3D, the memory device 1000A may detect whether one or more of the through-silicon vias are defective, using a test logic used when an SRAM is tested. In this case, no additional logic circuit is required, so that the memory device 1000A may effectively perform a test operation on the through-silicon vias without any additional overhead.

In addition, the memory device 1000A may perform a test operation on the through-silicon vias by adjusting periods of a clock signal and a data input signal. Because the periods of the clock signal and the data input signals may be set to be short, the memory device 1000A may perform a test operation on the through-silicon vias at high speed.

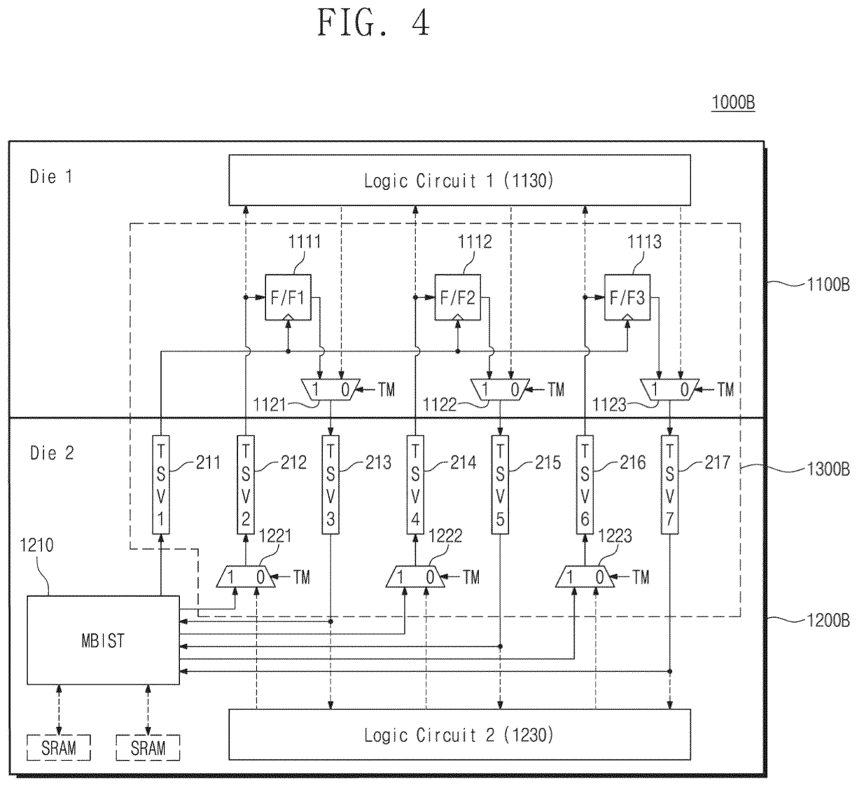

FIG. 4 is a block diagram illustrating a memory device 1000B according to an example embodiment. The memory device 1000B of FIG. 4 is similar to the memory devices 1000 and 1000A of FIGS. 1 and 2. Therefore, the same or similar components will be represented by the same or similar reference numerals, and redundant descriptions will be omitted.

For ease of description, an example will be provided in which a first die 1100B and a second die 1200B include a first logic circuit 1130 and a second logic circuit 1230, respectively. When the memory device 1000B is operating in a normal mode such as a read operation, a write operation, a calculation operation, or a data processing operation, the first logic circuit 1130 of the first die 1100B and the second logic circuit 1230 of the second die 1200B may be electrically connected to each other.

The memory device 1000B may support a switching operation between a test mode and a normal mode, and in this regard may selectively operate in the test mode and the normal mode. To this end, the memory device 1000B may further include mode multiplexers.

Referring to FIG. 4, the memory device 1000B may include a first die 1100B and a second die 1200B.

The first die 1100B may include first to third flip-flops 1111 to 1113. Also, the first die 1100B may include a first logic circuit 1130 and first to third mode multiplexers 1121 to 1123.

The second die 1200B may include first to seventh through-silicon vias 211 to 217 and an MBIST 1210. Also, the second die 1200B may include a second logic circuit 1230 and fourth to sixth mode multiplexers 1221 to 1223.

A virtual memory circuit 1300B may be formed across the first die 1100B and the second die 1200B. The virtual memory circuit 1300B may include the first to third flip-flops 1111 to 1113 and the first to seventh through-silicon vias 211 to 217. According to example embodiments, the virtual memory circuit 1300B may include mode multiplexers 1121 to 1123 and 1221 to 1223.

In an example embodiment, the memory device 1000B may support the test mode and the normal mode. The mode multiplexers 1121 to 1123 and 1221 to 1223 of the memory device 1000B may perform a switching operation between the test mode and the normal mode.

In the test mode, the MBIST 1210 of the second die 1200B may be electrically connected to the virtual memory circuit 1300B by the mode multiplexers 1221 to 1223. Accordingly, a detection may be made as to whether one or more of the first to seventh through-silicon vias 211 to 217 are defective.

In the normal mode, the first logic circuit 1130 of the first die 1100B may be electrically connected to the second logic circuit 1230 of the second die 1200B by the mode multiplexers 1121 to 1123 and 1221 to 1223. Accordingly, an operation of the memory device 1000B in the normal mode, such as a read operation, a write operation, or a calculation operation, may be performed.

As described above, the switching operation between the test mode and the normal mode may be supported, and in this regard the memory device 1000B may detect not only a defect in through-silicon vias during a memory manufacturing process, but also a defect caused by deterioration or damage of the through-silicon vias due to use thereof.

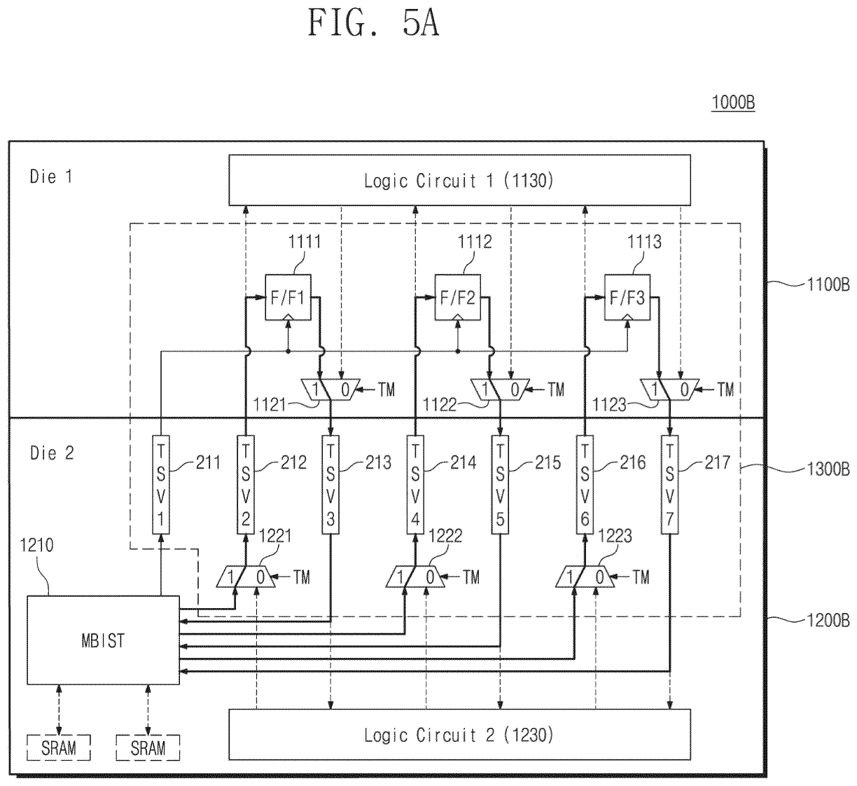

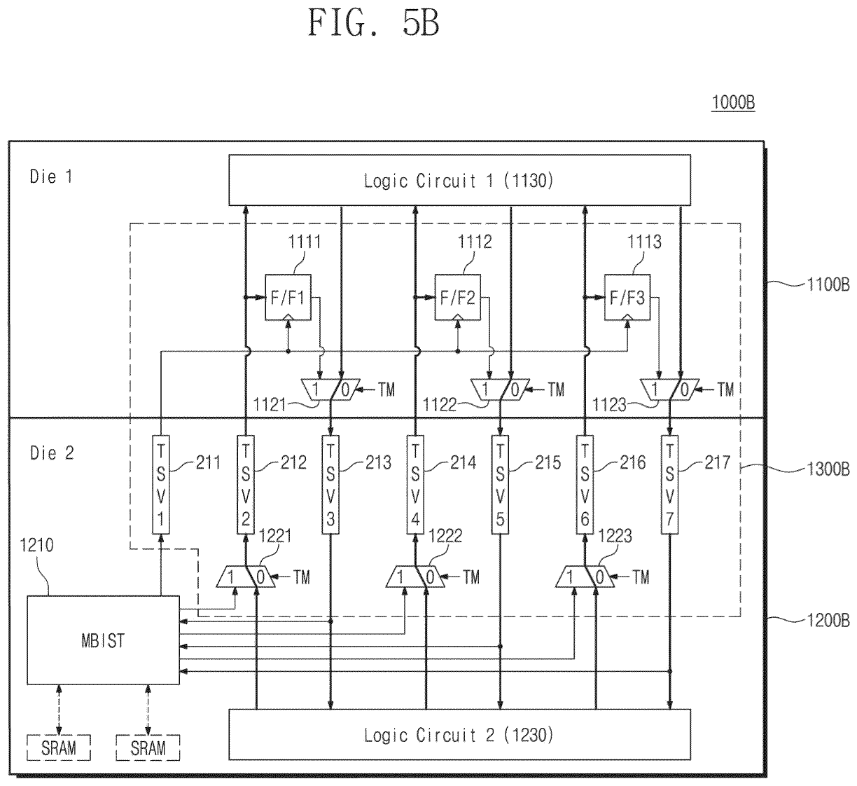

FIG. 5A is a diagram illustrating an example of an operation of the memory device 1000B of FIG. 4 in a test mode, and FIG. 5B is a diagram illustrating an example of an operation of the memory device 1000B of FIG. 4 in a normal mode.

Referring to FIG. 5A, in the test mode, a test mode signal TM may be set to “1.” Accordingly, fourth to sixth mode multiplexers 1221 to 1223 of the second die 1200B may each electrically connect the MBIST 1210 and a through-silicon via. In addition, first to third mode multiplexers 1121 to 1123 of the first die 1100B may each electrically connect a flip-flop and a through-silicon via. Accordingly, the MBIST 1210 may be electrically connected to the virtual memory circuit 1300B in the test mode.

A test operation may be performed on the virtual memory circuit 1300B to detect whether one or more of the first to seventh through-silicon vias 211 to 217 are defective.

Referring to FIG. 5B, in the normal mode, a test mode signal TM may be set to “0.” Accordingly, the fourth to sixth mode multiplexers 1221 to 1223 of the second die 1200B may each electrically connect the second logic circuit 1230 and the through-silicon via. In addition, the first to third mode multiplexers 1121 to 1123 of the first die 1100B may each electrically connect the first logic circuit 1130 and the through-silicon via. Accordingly, in the normal mode, the first logic circuit 1130 of the first die 1100B and the second logic circuit 1230 of the second die 1200B may be electrically connected to each other through the first to seventh through-silicon vias 211 to 217.

The memory device 1000B may perform an operation in the normal mode, such a read operation, a write operation, or a calculation operation.

As described above, the memory device 1000B may support a switching operation between the test mode and the normal mode.

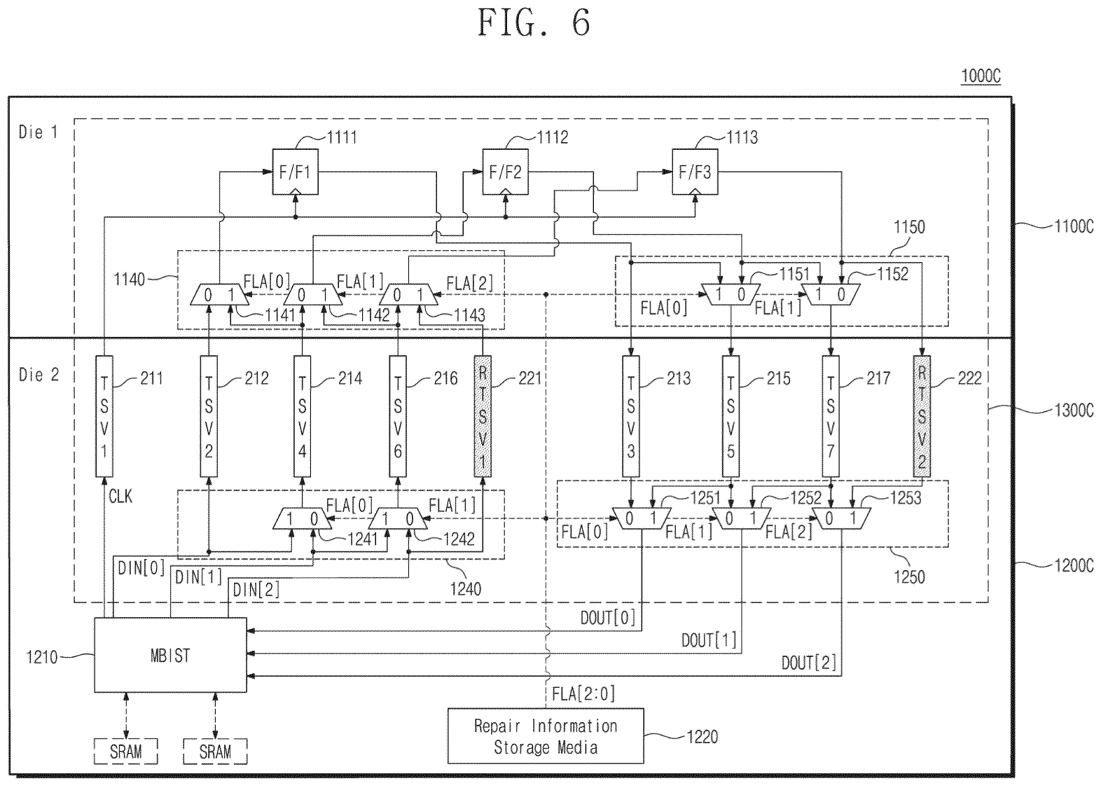

FIG. 6 is a block diagram illustrating a memory device 1000C according to an example embodiment. The memory device 1000C of FIG. 6 is similar to the memory devices 1000 and 1000A of FIGS. 1 and 2. Therefore, the same or similar components will be represented by the same or similar reference numerals, and redundant descriptions will be omitted.

For ease of description, an example will be provided in which the memory device 1000C includes two redundancy through-silicon vias 221 and 222.

The memory device 1000C may perform a repair operation on a defective through-silicon via. To this end, the memory device 1000C may include redundant through-silicon vias and shift circuits.

A detailed description is now provided with reference to FIG. 6. The memory device 1000C may include a first die 1100C and a second die 1200C.

The first die 1100C may include first to third flip-flops 1111 to 1113. Also, the first die 1100C may include a first shift circuit 1140 and a second shift circuit 1150.

The first shift circuit 1140 may include first to third shift multiplexers 1141 to 1143.

An input terminal of the first shift multiplexer 1141 may be connected to second and fourth through-silicon vias 212 and 214, and an output terminal of the first shift multiplexer 1141 may be connected to an input terminal of the first flip-flop 1111. The first shift multiplexer 1141 may electrically connect either the second through-silicon via 212 or the fourth through-silicon via 214 to the input terminal of the first flip-flop 1111 according to a 0th flag signal FLA[0].

An input terminal of the second shift multiplexer 1142 may be connected to the fourth and sixth through-silicon vias 214 and 216, and an output terminal of the second shift multiplexer 1142 may be connected to an input terminal of the second flip-flop 1112. The second shift multiplexer 1142 may electrically connect either the fourth through-silicon via 214 or the sixth through-silicon via 216 to the input terminal of the second flip-flop 1112 according to a first flag signal FLA[1].

An input terminal of the third shift multiplexer 1143 may be connected to the sixth through-silicon via 216 and the first redundancy through-silicon via 221, and an output terminal of the third shift multiplexer 1143 may be connected to an input terminal of the third flip-flop 1113. The third shift multiplexer 1143 may electrically connect either the sixth through-silicon via 216 or the first redundancy through-silicon via 221 to the input terminal of the third flip-flop 1113 according to a second flag signal FLA[2].

The second shift circuit 1150 may include a fourth shift multiplexer 1151 and a fifth shift multiplexer 1152.

An input terminal of the fourth shift multiplexer 1151 may be connected to an output terminal of the first flip-flop 1111 and an output terminal of the second flip-flop 1112, and an output terminal of the fourth shift multiplexer 1151 may be connected to the fifth through-silicon via 215. The fourth shift multiplexer 1151 may electrically connect either the output terminal of the first flip-flop 1111 or the output terminal of the second flip-flop 1112 to the fifth through-silicon via 215 according to the 0th flag signal FLA[0].

An input terminal of the fifth shift multiplexer 1152 may be connected to an output terminal of the second flip-flop 1112 and an output terminal of the third flip-flop 1113, and the output terminal of the fifth shift multiplexer 1152 may be connected to the seventh through-silicon via 217. The fifth shift multiplexer 1152 may electrically connect either the output terminal of the second flip-flop 1112 or the output terminal of the third flip-flop 1113 to the seventh through-silicon via 217 according to the first flag signal FLA[1].

The second die 1200C may include first to seventh through-silicon vias 211 to 217 and an MBIST 1210. Also, the second die 1200C may include first and second redundancy through-silicon vias 221 and 222, a third shift circuit 1240, and a fourth shift circuit 1250.

The third shift circuit 1240 may include a sixth multiplexer 1241 and a seventh shift multiplexer 1242.

An input terminal of the sixth shift multiplexer 1241 may receive the zeroth and first data input signals DIN[0] and DIN[1], and an output terminal pf the sixth shift multiplexer 1241 may be connected to the fourth through-silicon via 214. The sixth shift multiplexer 1241 may transmit either the zeroth data input signal DIN[0] or the first data input signal DIN[1] to the fourth through-silicon via 214 according to the 0th flag signal FLA[0].

An input terminal of the seventh shift multiplexer 1242 may receive the first and second data input signals DIN[1] and DIN[2], and an output terminal of the seventh shift multiplexer 1242 may be connected to the sixth through-silicon via 216. The seventh shift multiplexer 1242 may transmit either the first data input signal DIN[1] or the second data input signal DIN[2] to the sixth through-silicon via 216 according to the first flag signal FLA[1].

The fourth shift circuit 1250 may include eighth to tenth shift multiplexers 1251 to 1253.

An input terminal of the eighth shift multiplexer 1251 may be connected to the third and fifth through-silicon vias 213 and 215. The eighth shift multiplexer 1251 may output one of the signals, transmitted through the third and fifth through-silicon vias 213 and 215, as the 0th data output signal DOUT[0] according to the 0th flag signal FLA[0].

An input terminal of the ninth shift multiplexer 1252 may be connected to the fifth and seventh through-silicon vias 215 and 217. The ninth shift multiplexer 1252 may output one of the signals, transmitted through the fifth and seventh through-silicon vias 215 and 217, as the first data output signal DOUT[1] according to the first flag signal FLA[1].

An input terminal of the tenth shift multiplexer 1253 may be connected to the seventh through-silicon via 217 and the second redundancy through-silicon via 222. The tenth shift multiplexer 1253 may output one of the signals, transmitted through the seventh through-silicon via 217 and the second redundancy through-silicon via 222, as the second data output signal DOUT[2] according to the second flag signal FLA[2].

A virtual memory circuit 1300C may be formed across the first die 1100C and the second die 1200C. The virtual memory circuit 1300C may include the first to third flip-flops 1111 to 1113, the first to seventh through-silicon vias 211 to 217, and the first and second redundancy through-silicon vias 221 to 222. According to example embodiments, the virtual memory circuit 1300C may include the first to fourth shift circuits 1140, 1150, 1240, 1250.

According to example embodiments, the memory device 1000C may perform a repair operation on a defective through-silicon via. For example, when one of the first to seventh through-silicon vias 211 to 217 are determined to be defective, the memory device 1000C may replace the defective through-silicon via with a redundancy through-silicon via. For example, the memory device 1000C may identify the defective through-silicon via and utilize the redundancy through-silicon via to avoid the defective through-silicon via.

The first redundancy through-silicon via 221 may be provided to perform a repair operation on a through-silicon via, among upward through-silicon vias. The upward through-silicon via may refer to a through-silicon via for transmitting a signal from the second die 1200C to the first die 1100C.

For example, each of the second, fourth, and sixth through-silicon vias 212, 214, and 216 may receive a data input signal and may correspond to an upward through-silicon via, as illustrated in FIG. 6. When one of the second, fourth, and sixth through-silicon vias 212, 214, and 216 is defective, the first redundancy through-silicon via 221 may replace the defective through-silicon via. For example, the memory device 1000C may identify the defective through-silicon via and utilize the redundancy through-silicon via to avoid the defective through-silicon via.

The second redundancy through-silicon via 222 may be provided to perform a repair operation on a defective through-silicon via, among downward through-silicon vias. The downward through-silicon via may refer to a through-silicon via for transmitting a signal from the first die 1100C to the second die 1200C.

For example, each of the third, fifth, and seventh through-silicon vias 213, 215, and 217 may receive a data output signal and may correspond to a downward through-silicon via, as illustrated in FIG. 6. When one of the third, fifth, and seventh through-silicon vias 213, 215, and 217 is defective, the second redundancy through-silicon via 222 may replace the defective through-silicon via. For example, the memory device 1000C may identify the defective through-silicon via and utilize the second redundancy through-silicon via to avoid the defective through-silicon via.

The first to fourth shift circuits 1140, 1150, 1240, and 1250 may operate according to the flag signal FLA[2:0] and may select a redundancy through-silicon via instead of a defective through-silicon via.

For example, the first and third shift circuits 1140 and 1240 may be electrically connected to the upward through-silicon vias 212, 214, and 216 and the first redundancy through-silicon via 221, as illustrated in FIG. 6. When one of the upward through-silicon vias 212, 214, 216 is defective, the first and third shift circuits 1140 and 1240 may block a signal transmission path through the defective through-silicon via and generate a signal transmission path through the first redundancy through-silicon via 221.

Additionally, for example, the second and fourth shift circuits 1150, 1250 may be electrically connected to the downward through-silicon vias 213, 215, 217 and the second redundancy through-silicon via 222. When one of the downward through-silicon vias 213, 215, and 217 is defective, the second and fourth shift circuits 1150 and 1250 may block a signal transmission path through the defective through-silicon via and generate a signal transmission path through the second redundancy through-silicon via 222.

As described above, the memory device 1000C may support a repair operation on a defective through-silicon via.

In addition, according to an example embodiment, the second die 1200C may further include a repair information storage medium 1220. The repair information storage medium 1220 may store information on a flag signal FLA[2:0] used in the repair operation.

The repair information storage medium 1220 may be implemented as a nonvolatile memory such as a one-time programmable (OTP) memory, an e-fuse, a flash memory, or the like. Accordingly, information on the flag signal FLA[2:0] used in the repair operation may be continuously maintained. As a result, even when the memory device 1000C is powered off and then powered on again, the memory device 1000C does not need to perform the operation of detecting a defective through-silicon via and the repair operation again and may stably operate.

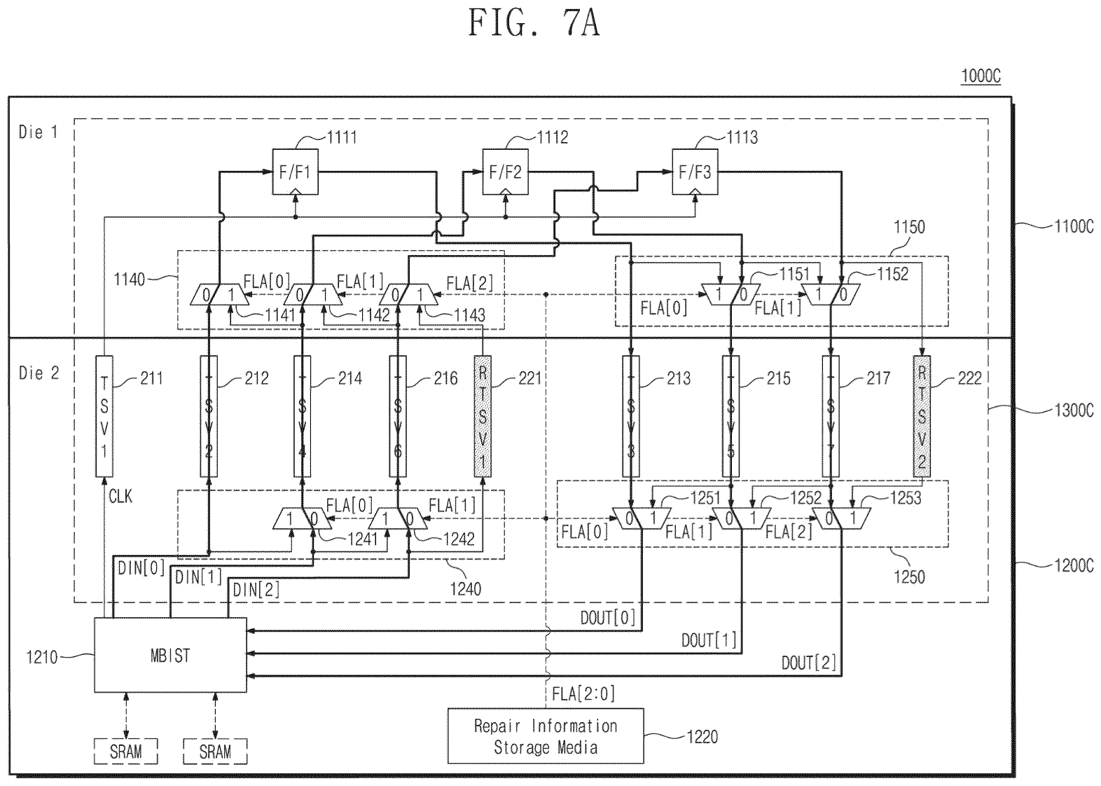

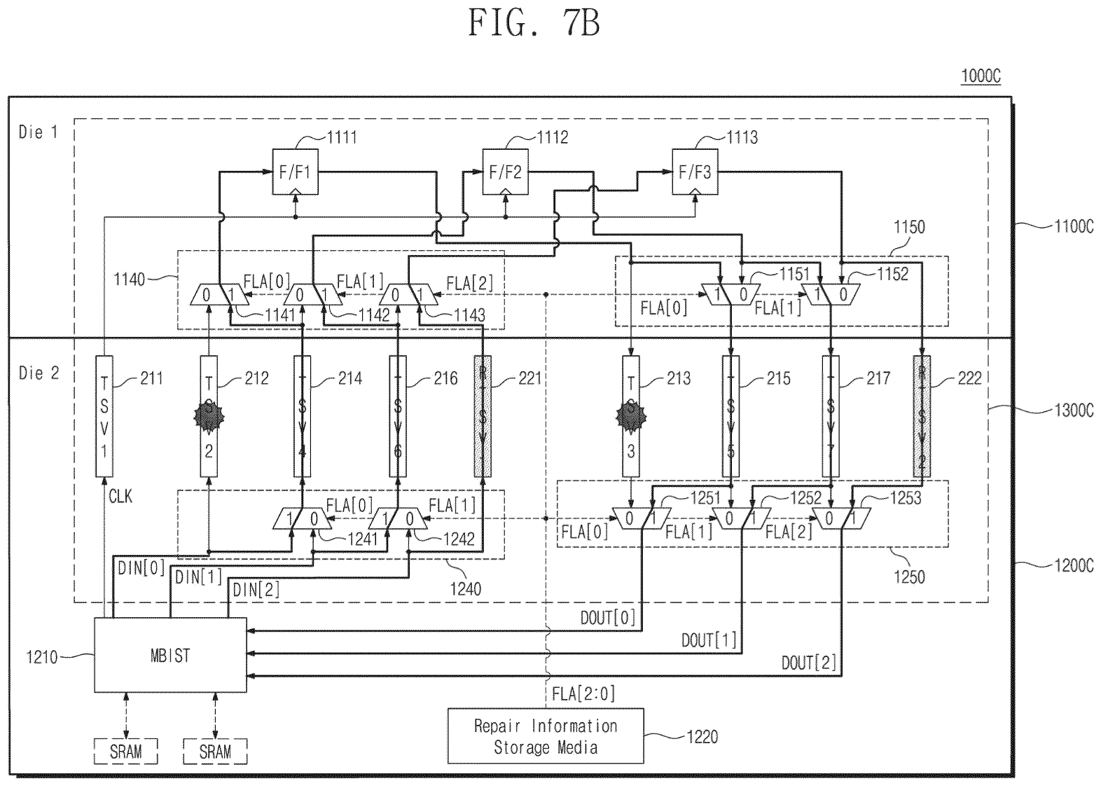

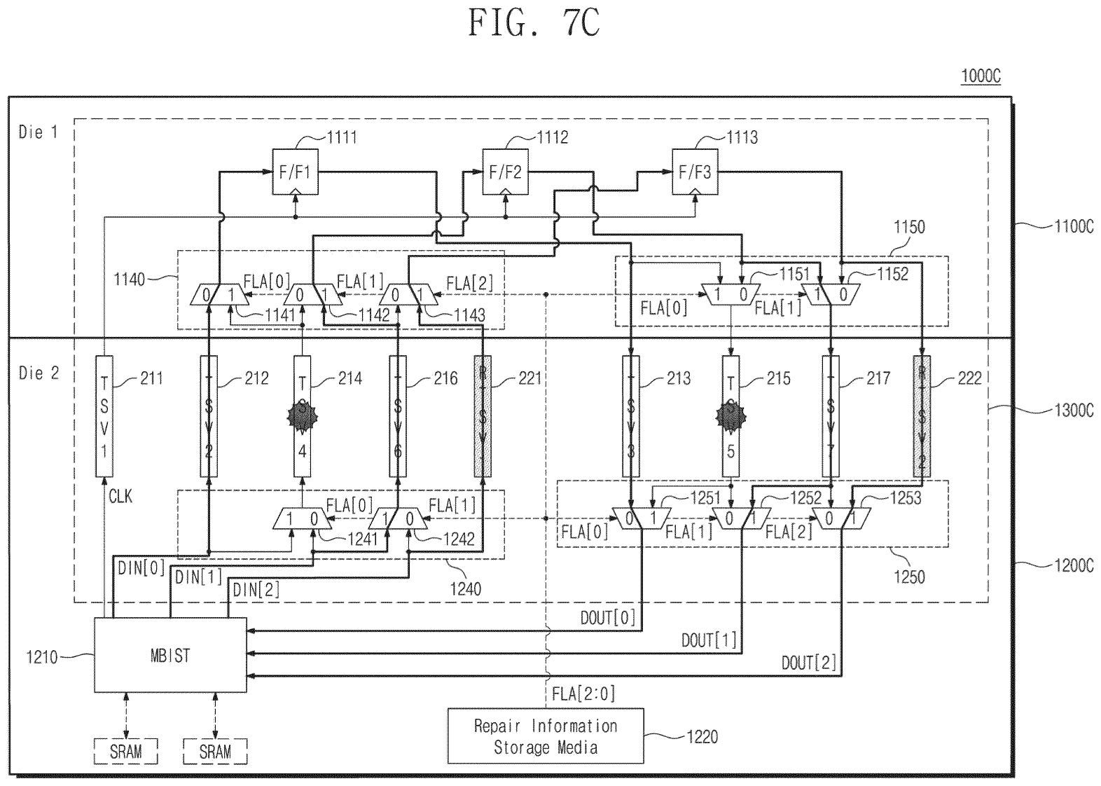

FIGS. 7A to 7C are diagrams illustrating a repair operation of the memory device 1000C of FIG. 6. FIG. 7A is a diagram illustrating an example of an operation of the memory device 1000C of FIG. 6 when there is no defect in through-silicon vias. FIG. 7B is a diagram illustrating an example of a repair operation of the memory device 1000C of FIG. 6 when a defect occurs in at least one of the second and third through-silicon vias 212 and 213. FIG. 7C is a diagram illustrating an example of a repair operation of the memory device 1000C of FIG. 6 when a defect occurs in at least one of the fourth and fifth through-silicon vias 214 and 215.

For ease of description, similarly to what is described with reference to FIGS. 2 and 3, an example will be provided in which when it is determined that at least one through-silicon vias connected to an input terminal and an output terminal of a flip-flop is defective, all through-silicon vias are connected to the input and output terminals of the flip-flop are replaced with redundancy through-silicon vias.

Referring to FIG. 7A, an example is provided in which second to seventh through-silicon vias 212 to 217 are all normal. In this case, a 0th flag signal FLA[0], a first flag signal FLA[1], and a second flag signal FLA[2] may be selected as “0,” “0,” and “0,” respectively.

In this case, as shown in FIG. 7A, shift multiplexers 1141 to 1143, 1151, 1152, 1241, 1242, and 1251 to 1253 may form a signal transmission path according to the flag signal of “0.”

For example, the first shift multiplexer 1141 may connect the second through-silicon via 212 to an input terminal of the first flip-flop 1111 according to a 0th flag signal FLA[0] having a value of “0.” Accordingly, a 0th data input signal DIN[0] may be connected to the input terminal of the first flip-flop 1111. In addition, the eighth shift multiplexer 1251 may output a signal of the third through-silicon via 213, connected to an output terminal of the first flip-flop 1111, as a 0th data output signal DOUT[0] according to the 0th flag signal FLA[0] having a value of ‘0’. As a result, the input and output terminals of the first flip-flop 1111 may be electrically connected to the second through-silicon via 212 and the third through-silicon via 213, respectively.

Similarly, when the 0th flag signal FLA[0], the first flag signal FLA[1], and the second flag signal FLA[2] are respectively “0,” “0,” and “0,” an input terminal and an output terminal of the second flip-flop 1112 may be electrically connected to the fourth through-silicon via 214 and the fifth through-silicon via 215, respectively. In addition, an input terminal and an output terminal of the third flip-flop 1113 may be electrically connected to the sixth through-silicon via 216 and the seventh through-silicon via 217, respectively.

The flag signals of “0,” “0,” and “0” can be stored in the repair information storage medium 1220. Accordingly, even when the memory device 1000C is powered off and then powered on, the memory device 1000C may stably operate through normal through-silicon vias.

Referring to FIG. 7B, an example is provided in which at least one of the second and third through-silicon vias 212 and 213 is defective. In this case, the first flag signal FLA[0], the second flag signal FLA[1], and the third flag signal FLA[2] may be selected as “1,” “1,” and “1,” respectively. Accordingly, a signal transmission path passing through the second and third through-silicon vias 212, 213 is blocked, and the signal transmission path passing through the first and second redundancy through-silicon vias 221 and 222 may be formed.

For example, the first shift multiplexer 1141 and the sixth shift multiplexer 1241 may be electrically connected through the fourth through-silicon via 214 according to the first flag signal FLA[0] having a value of “1.” Accordingly, the first data input signal DIN[0] may be transmitted to the input terminal of the first flip-flop 1111 via the fourth through-silicon via 214. For example, a signal transmission path through the second through-silicon via 212 may be blocked, and the first data input signal DIN[0] may be transmitted to the input terminal of the first flip-flop 1111 through the signal transmission path including the fourth through-silicon via 214.

In addition, the fourth shift multiplexer 1151 and the eighth shift multiplexer 1251 may be electrically connected through the fifth through-silicon via 215 according to the first flag signal FLA[0] having a value of “1.” Accordingly, an output signal of the first flip-flop 1111 may be output as the first data output signal DOUT[0] via the fifth through-silicon via 215. For example, a signal transmission path through the third through-silicon via 213 is blocked, and the first data output signal DOUT[0] may be output through the signal transmission path including the fifth through-silicon via 215.

As a result, a signal transmission path through which the first data input signal DIN[0] and the first data output signal DOUT[0] are transmitted may be shifted, and the input terminal and output terminal of the first flip-flop 1111 may be electrically connected to the fourth through-silicon via 214 and the fifth through-silicon via 215, respectively.

Similarly, when the first flag signal FLA[0], the second flag signal FLA[1], and the third flag signal FLA[2] are respectively “1,” “1,” and “1,” a signal transmission path through which the first data input signal DIN[1] and the first data output signal DOUT[1] are transmitted may be shifted, and the input terminal and the output terminal of the second flip-flop 1112 may be electrically connected to the sixth through-silicon via 216 and the seventh through-silicon via 217, respectively. In addition, a signal transmission path through which the second data input signal DIN[2] and the second data output signal DOUT[2] are transmitted may be shifted, and the input terminal and the output terminal of the third flip-flop 1113 may be electrically connected to the first redundancy through-silicon via 221 and the second redundancy through-silicon via 222, respectively.

As described above, the signal transmission path through which the data input signal and the data output signal are transmitted may be shifted, and thus a repair operation may be performed on a defective through-silicon via.

The flag signals of “1,” “1,” and “1” may be stored in the repair information storage medium 1220. Accordingly, even when the memory device 1000C is powered off and then powered on, the memory device 1000C may stably operate through the first and second redundancy through-silicon vias 221 and 222 rather than the defective through-silicon vias 212 and 213.

Referring to FIG. 7C, an example is provided in which at least one of the fourth and fifth through-silicon vias 214 and 215 is defective. In this case, the first flag signal FLA[0], the second flag signal FLA[1], and the third flag signal FLA[2] may be selected as “0,” “1,” and “1.” Accordingly, a signal transmission path passing through the fourth and fifth through-silicon vias 214, 215 may be blocked, and a signal transmission path passing through the first and second redundancy through-silicon vias 221 and 222 may be formed.

For example, when the first flag signal FLA[0], the second flag signal FLA[1], and the third flag signal FLA[2] are respectively “0,” “1,” and “1,” a signal transmission path through which the first data input signal DIN[0] and the first data output signal DOUT[0] are transmitted may be maintained the same as in FIG. 7A. However, the signal transmission path through which the first data input signal DIN[1] and the first data output signal DOUT[1] are transmitted may be shifted, and the input terminal and the output terminal of the second flip-flop 1112 may be electrically connected to the sixth through-silicon via 216 and the seventh through-silicon via 217, respectively. In addition, the signal transmission path through which the second data input signal DIN[2] and the second data output signal DOUT[2] are transmitted may be shifted, and the input terminal and output terminal of the third flip-flop 1113 may be electrically connected to the first redundancy through-silicon via 221 and the second redundancy through-silicon via 222, respectively.

The flag signals of “0,” “1,” and “1” may be stored in the repair information storage medium 1220. Accordingly, even when the memory device 1000C is powered off and then powered on, the memory device 1000C may stably operate through the first and second redundancy through-silicon vias 221, 222 instead of the defective through-silicon vias 214 and 215.

When at least one of the sixth and seventh through-silicon vias 216, 217 is defective, a signal transmission path through which the second data input signal DIN[2] and the second data output signal DOUT[2] are transmitted may be shifted, and the input terminal and output terminal of the third flip-flop 1113 may be electrically connected to the first redundancy through-silicon via 221 and the second redundancy through-silicon via 222, respectively.

As described with reference to FIGS. 6 to 7C, the memory device 1000C according to an example embodiment may support a repair operation on a defective through-silicon via. For example, the memory device 1000C according to an example embodiment may by shift a signal transmission path, through which a data input signal and a data output signal are transmitted, to perform a repair operation on a defective through-silicon via.

In FIGS. 6 to 7C, a description has been provided for an example in which when it is determined that at least one through-silicon via connected to an input terminal and an output terminal of a flip-flop is defective, all through-silicon vias connected to the input terminal and output terminal of the flip-flop are replaced with redundancy through-silicon vias. However, this is only an example, and it should be understood that example embodiments are not limited thereto.

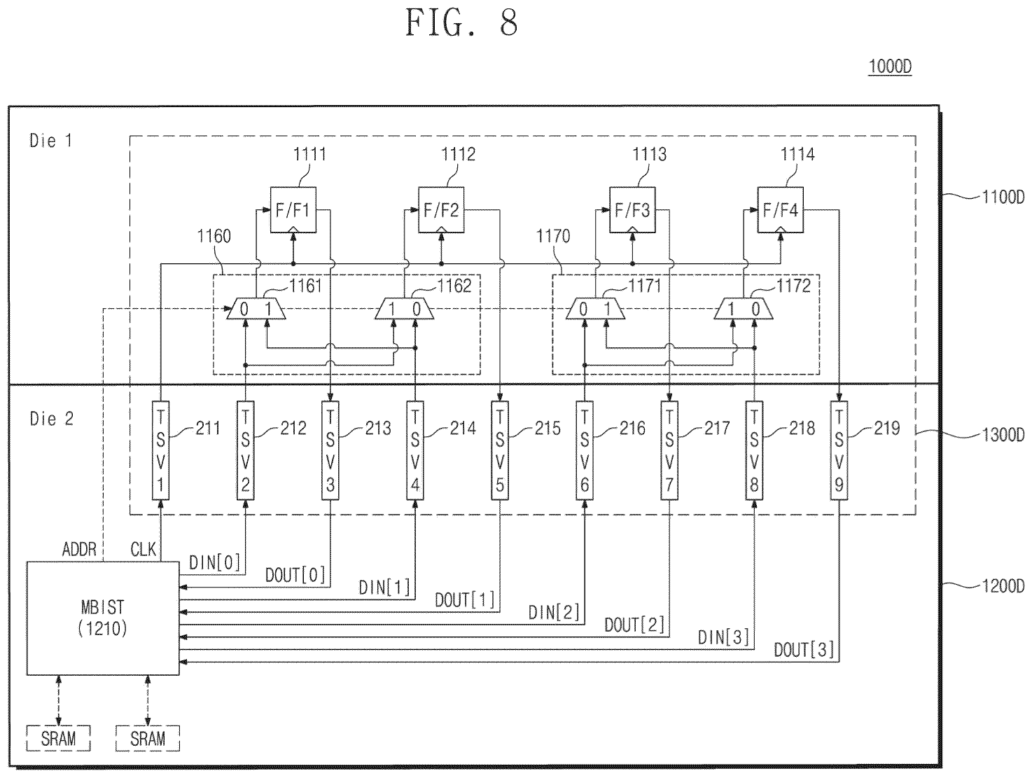

According to an example embodiment, as will be described with reference to FIGS. 8 to 12 below, a memory device according to an example embodiment may accurately identify a defective through-silicon via. In this case, the memory device according to an example embodiment may also perform a repair operation on the identified defective through-silicon via by setting values of flag signals, provided to shift multiplexers, in various ways.

FIG. 8 is a block diagram illustrating a memory device 1000D according to an example embodiment. The memory device 1000D of FIG. 8 is similar to the memory device 1000 and 1000A of FIGS. 1 and 2. Therefore, the same or similar components will be represented by the same or similar reference numerals, and redundant descriptions will be omitted.

For ease of description, an example will be provided in which decoding circuits 1160 and 1170 are formed on a first die 1100D. However, this is only an example, and example embodiments are not limited thereto. For example, in an example embodiment, the decoding circuits 1160 and 1170 may be formed on a second die 1200D.

The memory device 1000D according to an example embodiment may accurately identify a defective through-silicon via, among a plurality of through-silicon vias. To this end, the memory device 1000D may further include decoding circuits.

Referring to FIG. 8, for example, the memory device 1000D may include a first die 1100D and a second die 1200D.

The first die 1100D may include first to fourth flip-flops 1111 to 1114. The first die 1100D may further include a first decoding circuit 1160 and a second decoding circuit 1170.

The first decoding circuit 1160 may include a first multiplexer 1161 and a second decoding multiplexer 1162.

An input terminal of the first decoding multiplexer 1161 may be connected to the second and fourth through-silicon vias 212 and 214, and an output terminal of the first decoding multiplexer 1161 may be connected to an input terminal of the first flip-flop 1111. The first decoding multiplexer 1161 may electrically connect one of the second and fourth through-silicon vias 212 and 214 to an input terminal of the first flip-flop 1111 according to an address signal ADDR.

An input terminal of the second decoding multiplexer 1162 may be connected to the second and fourth through-silicon vias 212 and 214, and an output terminal of the second decoding multiplexer 1162 may be connected to an input terminal of the second flip-flop 1112. The second decoding multiplexer 1162 may electrically connect one of the second and fourth through-silicon vias 212 and 214 to the input terminal of the second flip-flop 1112 according to the address signal ADDR.

The second decoding circuit 1170 may include a third decoding multiplexer 1171 and a fourth decoding multiplexer 1172.

An input terminal of the third decoding multiplexer 1171 may be connected to the sixth and eighth through-silicon vias 216 and 218, and an output terminal of the third decoding multiplexer 1171 may be connected to an input terminal of the third flip-flop 1113. The third decoding multiplexer 1171 may electrically connect one of the sixth and eighth through-silicon vias 216 and 218 to the input terminal of the third flip-flop 1113 according to the address signal ADDR.

An input terminal of the fourth decoding multiplexer 1172 may be connected to the sixth and eighth through-silicon vias 216 and 218, and an output terminal of the fourth decoding multiplexer 1172 may be connected to an input terminal of the fourth flip-flop 1114. The fourth decoding multiplexer 1172 may electrically connect one of the sixth and eighth through-silicon vias 216 and 218 to the input terminal of the fourth flip-flop 1114 according to the address signal ADDR.

The second die 1200D may include first to ninth through-silicon vias 211 to 219 and an MBIST 1210.

A virtual memory circuit 1300D may be formed across the first die 1100D and the second die 1200D. The virtual memory circuit 1300D may include the first to fourth flip-flops 1111 to 1114 and the first to ninth through-silicon vias 211 to 219. In addition, according to an example embodiment, the virtual memory circuit 1300C may include the first and second decoding circuits 1160 and 1170.

In an example embodiment, the memory device 1000D may perform a switching operation, changing a through-silicon via connected to an input terminal of each flip-flop, to accurately detect a defective through-silicon via. For example, when it is determined that at least one of the two through-silicon vias corresponding to a specific flip-flop is defective, the memory device 1000D may electrically connect a normal through-silicon via to a through-silicon via that needs to be checked for defectiveness. Accordingly, the defective through-silicon via may be accurately detected.

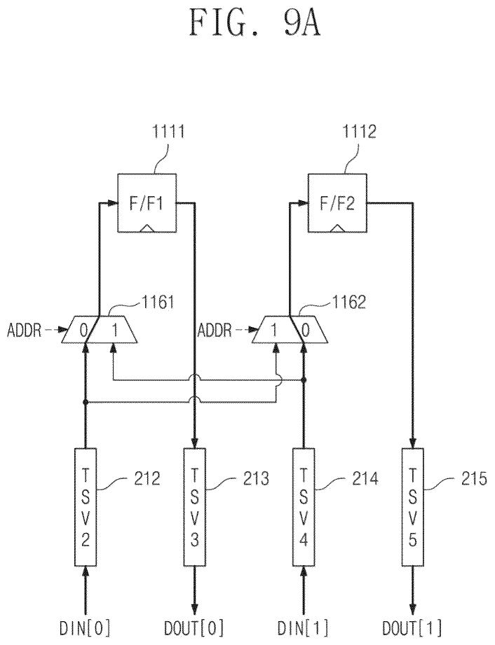

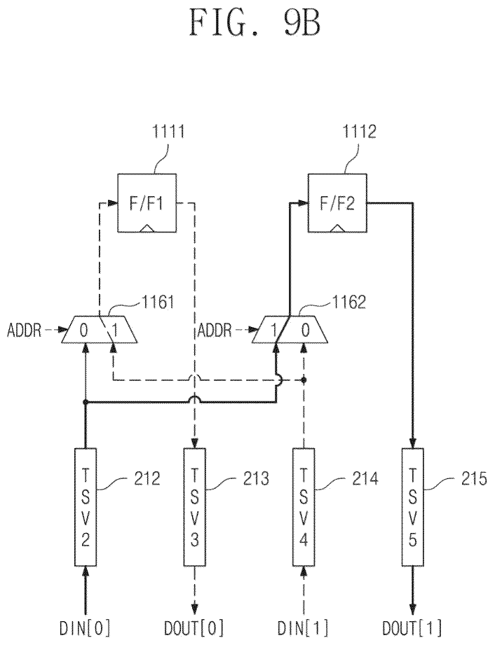

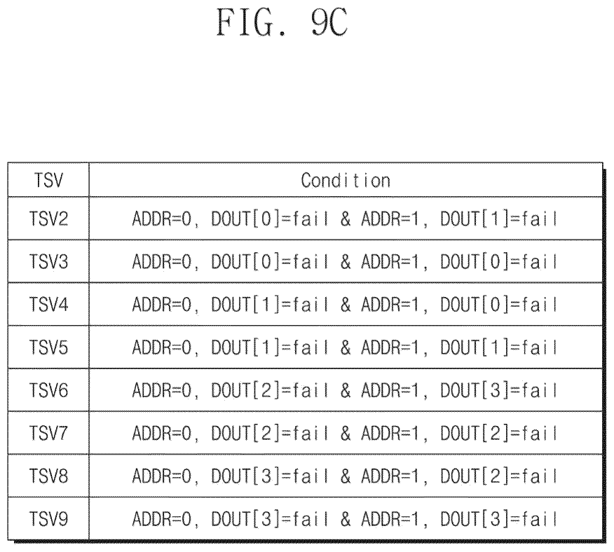

FIGS. 9A to 9C are diagrams illustrating an operation of the memory device 1000D of FIG. 8. FIG. 9A illustrates an example of a signal transmission path of the memory device 1000D when an address ADDR is “0.” FIG. 9B illustrates an example of a signal transmission path of the memory device 1000D when an address ADDR is “1.” FIG. 9C illustrates an example of a condition for identifying a defective through-silicon via, among second to ninth through-silicon vias.

For ease of description, operations related to the second to fifth through-silicon vias 212 to 215, among the first to ninth through-silicon vias 211 to 219, will be mainly described below.

Referring to FIG. 9A, the address ADDR may be set to “0.”

In this case, the first decoding multiplexer 1161 may connect the second through-silicon via 212 to the input terminal of the first flip-flop 1111 according to the address signal ADDR having a value of “0.” Accordingly, a 0th data input signal DIN[0] may be provided to the input terminal of the first flip-flop 1111.

In addition, the second decoding multiplexer 1162 responds to the address signal ADDR having a value of ‘0’ to connect the fourth through-silicon via 214 to the input terminal of the second flip-flop 1112. Accordingly, the first data input signal DIN[1] may be provided to the input terminal of the second flip-flop 1112.

For ease of description, similarly to FIGS. 2 and 3C, an example is provided in which at least one of the second and third through-silicon vias 212 and 213 is defective, and the fourth and fifth through-silicon vias 214 and 215 are normal.

In this case, when a test operation is performed on the virtual memory circuit 1300D, the 0th data output signal DOUT[0] may be fail and the 1st data output signal DOUT[1] may be pass. For example, based on a test result that the 0th data output signal DOUT[0] is fail in a state in which the address ADDR is “0,” the MBIST 1210 may first determine that at least one of the second and third through-silicon vias 212 and 213 is defective.

Referring to FIG. 9B, an address ADDR may be changed from “0” to “1” to accurately detect a defective through-silicon via, among the second and third through-silicon vias 212 and 213. This results in formation of a signal transmission path in which a through-silicon via, which needs to be checked for defectiveness, and a normal through-silicon via are electrically connected to each other. The MBIST 1210 may perform an additional test operation in a state in which the address ADDR is “1.” The defective through-silicon via, among the second and third through-silicon vias 212 and 213, may be accurately detected through the additional test operation.

A more detailed description is now provided. The MBIST 1210 may first change the address ADDR from “0” to “1.”

The first decoding multiplexer 1161 may connect the fourth through-silicon via 214 to the input terminal of the first flip-flop 1111 according to the address signal ADDR having a value of “1.” Accordingly, the fourth through-silicon via 214 may be connected to the input terminal of the first flip-flop 1111. For example, the fourth through-silicon via 214, which has been determined to be normal, may be connected to the input terminal of the first flip-flop 1111, and the third through-silicon via 213, which needs to be checked for defectiveness, may be connected to the output terminal of the first flip-flop 1111.

The second decoding multiplexer 1162 may connect the second through-silicon via 212 to the input terminal of the second flip-flop 1112 according to the address signal ADDR having a value of “1.” Accordingly, the second through-silicon via 212 may be connected to the input terminal of the second flip-flop 1112. For example, the second through-silicon via 212, which needs to be checked for defectiveness, may be connected to the input terminal of the second flip-flop 1112, and the fifth through-silicon via 215, which has been determined to be normal, may be connected to the output terminal of the second flip-flop 1112.

The MBIST 1210 may perform an additional test operation to accurately detect a defective through-silicon via, among the second and third through-silicon vias 212 and 213.

When the third through-silicon via 213 is defective, the 0th data output signal DOUT[0] output from the third through-silicon via 213 may be fail. For example, the fourth through-silicon via 214 is normal, so that the 0th data output signal DOUT[0] output from the third through-silicon via 213 may indicate a failure when the third through-silicon via 213 is defective. In contrast, when the third through-silicon via 213 is normal, the 0th data output signal DOUT[0] output from the third through-silicon via 213 may be pass.

When the second through-silicon via 212 is defective, the first data output signal DOUT[1] output from the fifth through-silicon via 215 may be fail. For example, the fifth through-silicon via 215 is normal, so that the first data output signal DOUT[1] output through the second through-silicon via 212 may be fail when the second through-silicon via 212 is defective. In contrast, when the second through-silicon via 212 is normal, the first data output signal DOUT[1] may be pass.

The 0th data output signal DOUT[0] in the additional test operations may be an output signal corresponding to the first data input signal DIN[1], and the first data output signal DOUT[1] in the additional test operation may be an output signal corresponding to the 0th data input signal DIN[0].

In summary, when the 0th data output signal DOUT[0] is fail in a state in which the address ADDR is set to “0” and the first data output signal DOUT[1] is fail in a state in which the address ADDR is set to “1,” the second through-silicon via 212 may be determined to be defective.

In addition, when the 0th data output signal DOUT[0] is fail in a state in which the address ADDR is set to “0” and the 0th data output signal DOUT[0] is fail in a state in which the address ADDR is set to “1,” the third through-silicon via 213 may be determined to be defective.

As described above, a signal transmission path may be formed to include a through-silicon via that has been determined to be normal and a through-silicon via that needs to be checked for infectiveness, and an additional test operation may then be performed. As a result, the memory device 1000D according to an example embodiment may accurately detect a defective through-silicon via.

Such a method of detecting a defective through-silicon via may be similarly applied to other through-silicon vias.

For example, referring to FIG. 9C, when the first data output signal DOUT[1] is fail in a state in which the address ADDR is set to “0” and the 0th data output signal DOUT[0] is fail in a state in which the address ADDR is set to “1,” the fourth through-silicon via 214 may be determined to be defective.

In addition, when the first data output signal DOUT[1] is fail in a case in which the address ADDR is set to “0” and the first data output signal DOUT[1] is fail in a case in which the address ADDR is set to “1,” the fifth through-silicon via 215 may be determined to be defective.

Similarly, each of the sixth to ninth through-silicon vias 216 to 219 may be accurately checked for defectiveness, under the conditions illustrated in FIG. 9C.

In FIGS. 8, 9A and 9B, the decoding circuits 1160 and 1170 have been described as being formed on the first die 1100D. However, this is only an example and example embodiments are not limited thereto. For example, according to an example embodiment, the decoding circuits 1160 and 1170 may be formed on the second die 1200D.

In FIGS. 2 to 9C, a description has been provided for an example in which a single through-silicon via corresponds to an input terminal or an output terminal of a single flip-flop. However, this is only an example and example embodiments are not limited thereto.

According to an example embodiment, the number of upward through-silicon vias may be greater than the number of downward through-silicon vias. In this case, at least two through-silicon vias may be connected to an output terminal of a single flip-flop.

Alternatively, according to an example embodiment, the number of downward through-silicon vias may be greater than the number of upward through-silicon vias. In this case, at least two through-silicon vias may be connected to an input terminal of a single flip-flop.

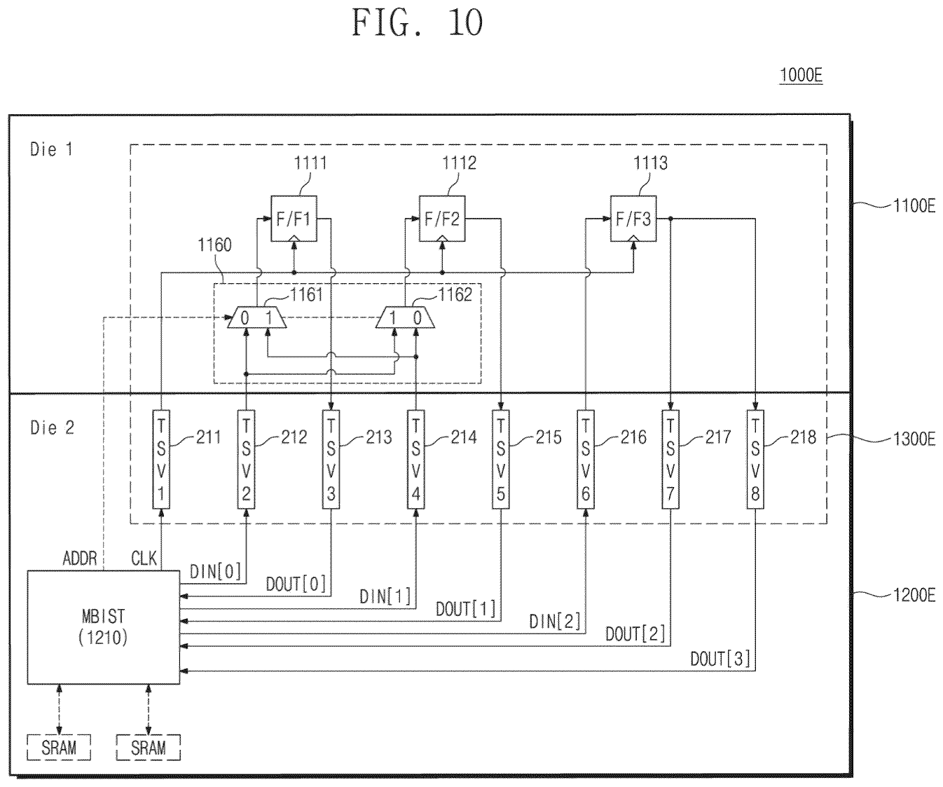

Even in such a case, the memory device according to an example embodiment may detect a defective through-silicon via and perform a repair operation on the defective through-silicon via. This will be described in more detail with reference FIGS. 10 to 13 below.

FIG. 10 is a block diagram illustrating a memory device 1000E according to an example embodiment. The memory device 1000E of FIG. 10 is similar to the memory devices 1000 and 1000D of FIGS. 1 and 8. Therefore, the same or similar components will be represented by the same or similar reference numerals, and redundant descriptions will be omitted. For ease of description, similarly to FIG. 8, an example will be provided in which first decoding circuits 1160 are formed on a first die 1100D.

In the memory device 1000E according to an example embodiment, the number of downward through-silicon vias may be greater than the number of upward through-silicon vias. Accordingly, at least two through-silicon vias may be connected to an output terminal of a single flip-flop. Even in this case, the memory device 1000E may accurately detect a defective through-silicon via.

A more detailed description is now provided with reference to FIG. 10. The memory device 1000E may include a first die 1100E and a second die 1200E.

The first die 1100E may include first to third flip-flops 1111 to 1113. In addition, the first die 1100E may include a first decoding circuit 1160. The first decoding circuit 1160 may include a first multiplexer 1161 and a second decoding multiplexer 1162.

The second die 1200E may include first to eighth through-silicon vias 211 to 218 and an MBIST 1210.

A virtual memory circuit 1300E may be formed across the first die 1100E and the second die 1200E. The virtual memory circuit 1300E may include first to third flip-flops 1111 to 1113 and first to eighth through-silicon vias 211 to 218. In addition, according to an example embodiment, the virtual memory circuit 1300E may include the first decoding circuit 1160.

In an example embodiment, in the memory device 1000E, the number of downward through-silicon vias may be greater than the number of upward through-silicon vias. For example, a single through-silicon via 216 may be electrically connected to an input terminal of the third flip-flop 1113, while two through-silicon vias 217 and 218 may be electrically connected to an output terminal of the third flip-flop 1113. Even in this case, the memory device 1000E according to an example embodiment may accurately detect a defective through-silicon via.

For example, in the case of the second to fifth through-silicon vias 212 to 215, the memory device 1000E may electrically connect a normal through-silicon via to a through-silicon via, which needs to be checked for defectiveness, using the first decoding circuit 1160. Thus, a defective through-silicon via, among the second to fifth through-silicon vias 212 to 215, may be accurately detected.

For example, in the case of the sixth to eighth through-silicon vias 216 to 218, the memory device 1000E may accurately detect a defective through-silicon via based on a test result.

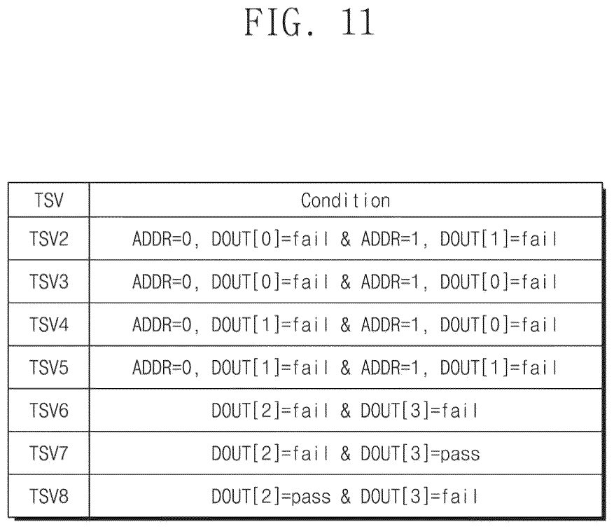

FIG. 11 is a diagram illustrating conditions for identifying a defective through-silicon via, among second to eighth through-silicon vias.

The conditions for determining whether one or more of the second to fifth through-silicon vias 212 to 215 are defective are the same as those described with reference to FIGS. 9B and 9C. Therefore, the following description will be provided for the conditions for determining whether one or more of the sixth to eighth through-silicon vias 216 to 218 are defective.

Referring to FIGS. 10 and 11, the sixth through-silicon via 216 may be connected to an input terminal of the third flip-flop 1113, and the seventh and eighth through-silicon vias 217 and 218 may be connected to an output terminal of the third flip-flop 1113.

Therefore, when the sixth through-silicon via 216 is defective, a second data input signal DIN[2] may be distorted by the sixth through-silicon via 216, and thus second and third data output signals DOUT[2] and DOUT[3] may also be distorted. As a result, regardless of whether the address ADDR is “0” or “1,” the sixth through-silicon via 216 may be determined to be defective when both the second data output signal DOUT[2] and the third data output signal DOUT[3] are fail.

In addition, when the seventh through-silicon via 217 is defective, only the second data output signal DOUT[2] may be distorted. As a result, regardless of whether the address ADDR is “0” or “1,” the seventh through-silicon via 217 may be determined to be defective when the second data output signal DOUT[2] is fail and the third data output signal DOUT[3] is pass.

In addition, when the eighth through-silicon via 218 is defective, only the third data output signal DOUT[3] may be distorted. As a result, regardless of whether the address ADDR is “0” or “1,” the eighth through-silicon via 218 may be determined to be defective when the second data output signal DOUT[2] is pass and the third data output signal DOUT[3] is fail.

As described above, in the memory device 1000E according to an example embodiment, the number of downward through-silicon vias may be greater than the number of upward silicon vias. Even in this case, the memory device 1000E may accurately detect a defective silicon via.

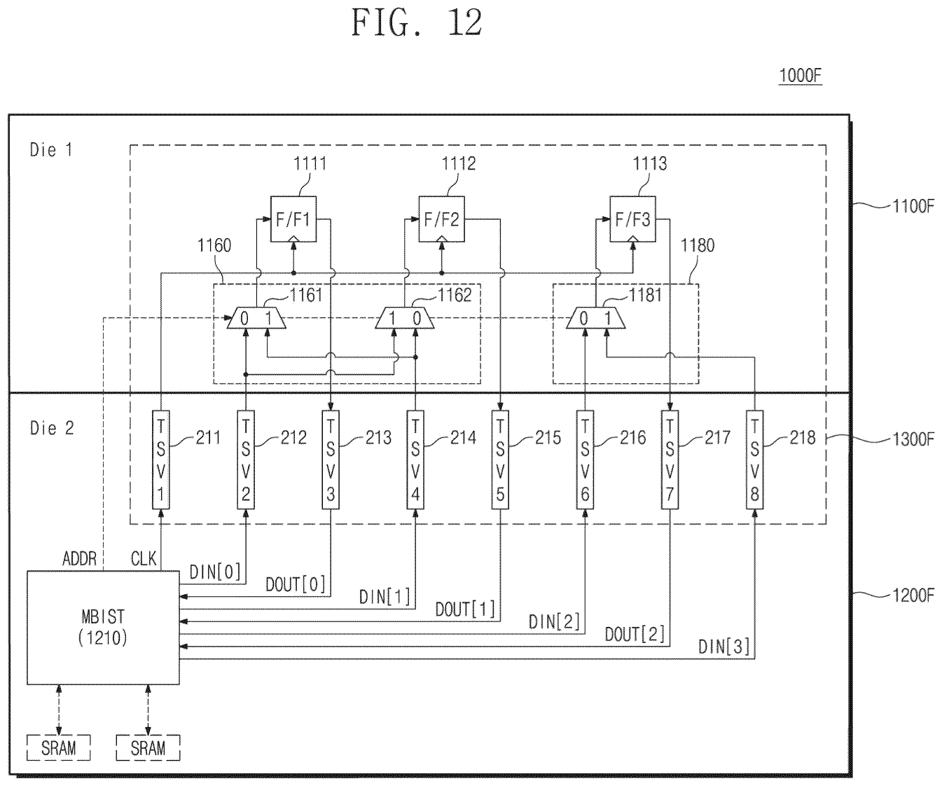

FIG. 12 is a block diagram illustrating a memory device 1000F according to an example embodiment. The memory device 1000F of FIG. 12 is similar to the memory devices 1000 and 1000E of FIGS. 1 and 10. Therefore, the same or similar components will be represented by the same or similar reference numerals, and redundant descriptions will be omitted. For ease of description, an example will be provided in which a first decoding circuit 1160 and a third decoding circuit 1180 are formed on a first die 1100D.

In the memory device 1000E according to an example embodiment, the number of upward through-silicon vias may be greater than the number of downward through-silicon vias. Accordingly, at least two through-silicon vias may be connected to an input terminal of a flip-flop. Even in this case, the memory device 1000F may accurately detect a defective through-silicon via.

A more detailed description will be provided with reference to FIG. 12. The memory device 1000F may include a first die 1100F and a second die 1200F.

The first die 1100F may include first to third flip-flops 1111 to 1113. In addition, the first die 1100F may include first and third decoding circuits 1160 and 1180. The first decoding circuit 1160 may include first and second decoding multiplexers 1161 and 1162, and the third decoding circuit 1180 may include a fifth decoding multiplexer 1181.

The second die 1200F may include first to eighth through-silicon vias 211 to 218 and an MBIST 1210.

A virtual memory circuit 1300F may be formed across the first die 1100F and the second die 1200F. The virtual memory circuit 1300F may include first to third flip-flops 1111 to 1113 and first to eighth through-silicon vias 211 to 218. In addition, according to an example embodiment, the virtual memory circuit 1300F may include a first decoding circuit 1160 and a third decoding circuits 1180.

In an example embodiment, in the memory device 1000F, the number of upward through-silicon vias may be greater than the number of downward through-silicon vias. For example, two through-silicon vias 216 and 218 may be electrically connected to an input terminal of the third flip-flop 1113, and a single through-silicon via 217 may be electrically connected to an output terminal of the third flip-flop 1113. Even in this case, the memory device 1000F may accurately detect a defective through-silicon via.

For example, in the case of the second to fifth through-silicon vias 212 to 215, the memory device 1000F may electrically connect a normal through-silicon via to a through-silicon via, which needs to be checked for defectiveness, using the first decoding circuit 1160. Accordingly, a defective through-silicon via, among the second to fifth through-silicon vias 212 to 215, may be accurately detected.

For example, in the case of the sixth to eighth through-silicon vias 216 to 218, the memory device 1000F may electrically connect a normal through-silicon via to a through-silicon via, which needs to be checked for defectiveness, using the third decoding circuit 1180. Accordingly, a defective through-silicon via, among the sixth to eighth through-silicon vias 216 to 218, may be accurately detected.

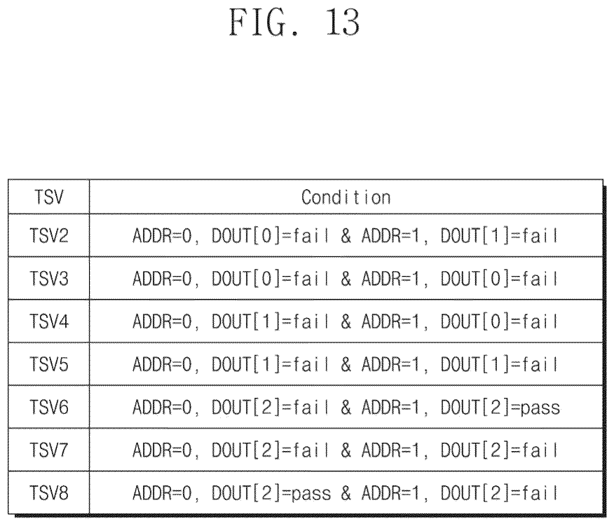

FIG. 13 is a diagram illustrating conditions for identifying a defective through-silicon via, among second to eighth through-silicon vias.

The conditions for determining whether one or more of sixth to eighth through-silicon vias 216 to 218 are defective are the same as those described with reference to FIGS. 9B and 9C. Therefore, the following description will be provided for the conditions for determining whether one or more of the sixth to eighth through-silicon vias 216 to 218 are defective.

Referring to FIGS. 12 and 13, the sixth and eighth through-silicon vias 216 and 218 may be connected to an input terminal of the third flip-flop 1113, and the seventh through-silicon via 217 may be connected to an output terminal of the third flip-flop 1113.

A test operation may be performed in a state in which an address ADDR is set to “0.”

When a second data output signal DOUT[2] is fail in a state in which the address ADDR is set to “0,” at least one of the sixth and seventh through-silicon vias 216 and 217 may be defective.

In this case, an additional test operation may be performed in a case in which the address ADDR is changed from “0” to “1.” When the second data output signal DOUT[2] is pass in a state in which the address ADDR is set to “1,” the sixth through-silicon via 216 may be determined to be defective. When the second data output signal DOUT[2] is fail in a state in which the address ADDR is set to “1,” the seventh through-silicon via 217 may be determined to be defective.

When the second data output signal DOUT[2] is pass in a case in which the address ADDR is set to “0,” the sixth and seventh through-silicon vias 216 and 217 may be normal. In this case, an additional test operation may be performed in a state in which the address ADDR is changed from “0” to “1.” When the second data output signal DOUT[2] is fail in a state in which the address ADDR is set to “1,” the eighth through-silicon via 218 may be determined to be defective.

As described above, in the memory device 1000F according to an example embodiment, the number of upward through-silicon vias may be greater than the number of downward through-silicon vias. In this case, the memory device 1000F may accurately detect a defective through-silicon via.

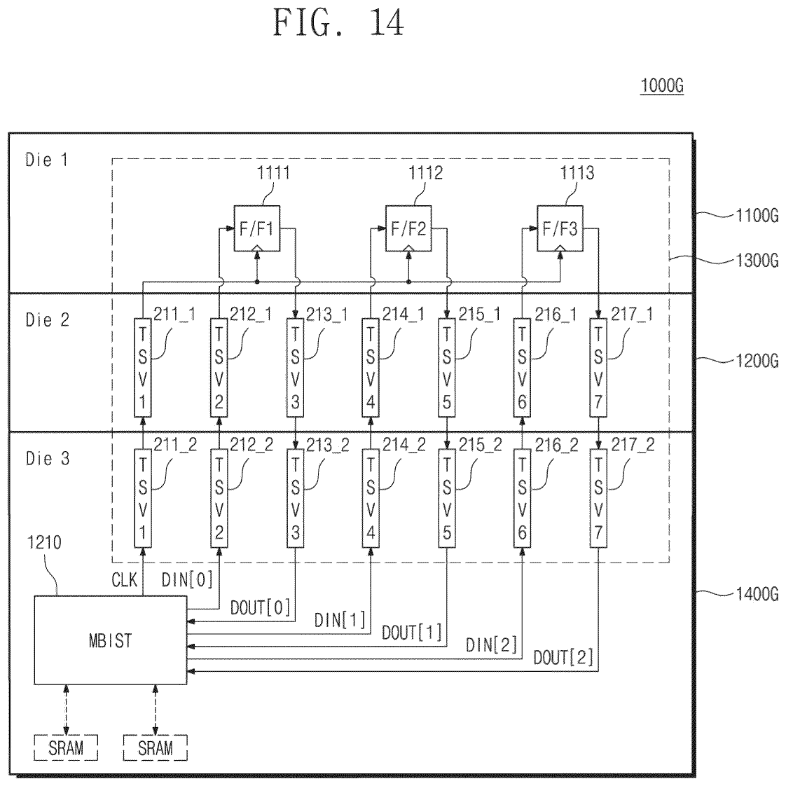

FIG. 14 is a block diagram illustrating a memory device 1000G according to an example embodiment. The memory device 1000G of FIG. 14 is similar to the memory devices 1000 and 1000A of FIGS. 1 and 2. Therefore, the same or similar components will be represented by the same or similar reference numerals, and redundant descriptions will be omitted.

In the previous description, the memory devices 1000 and 1000A to 1000F have been described as including two dies. However, it should be understood that this is only an example and example embodiments are not limited thereto. The memory device according to example embodiments may also be applied to a case in which three or more dies are stacked in a vertical direction or disposed in a horizontal direction.

For example, the memory device 1000G may include first to third dies 1100G, 1200G, and 1400G. The second die 1200G may include a plurality of through-silicon vias 211_2 to 217_2 to electrically connect the first die 1100G and the second die 1200G, and the third die 1400G may include a plurality of through-silicon vias 211_2 to 217_2 to electrically connect the second die 1200G and the third die 1400G.

In this case, the memory device 1000G may configure a virtual memory circuit 1300G to detect a defective through-silicon via, among the plurality of through-silicon vias 211_1 to 217_1 and 211_2 to 217_2. For example, the first die 1100G may be implemented to include a plurality of flip-flops 1111 to 1113 and the third die 1400G may be implemented to include an MBIST 1210, and the virtual memory circuit 1300G may be configured across the first, second, and third dies 1100G, 1200G, and 1400G. Accordingly, a defective through-silicon via, among the plurality of through-silicon vias 211_1 to 217_1 and 211_2 to 217_2, may be detected without any additional overhead.

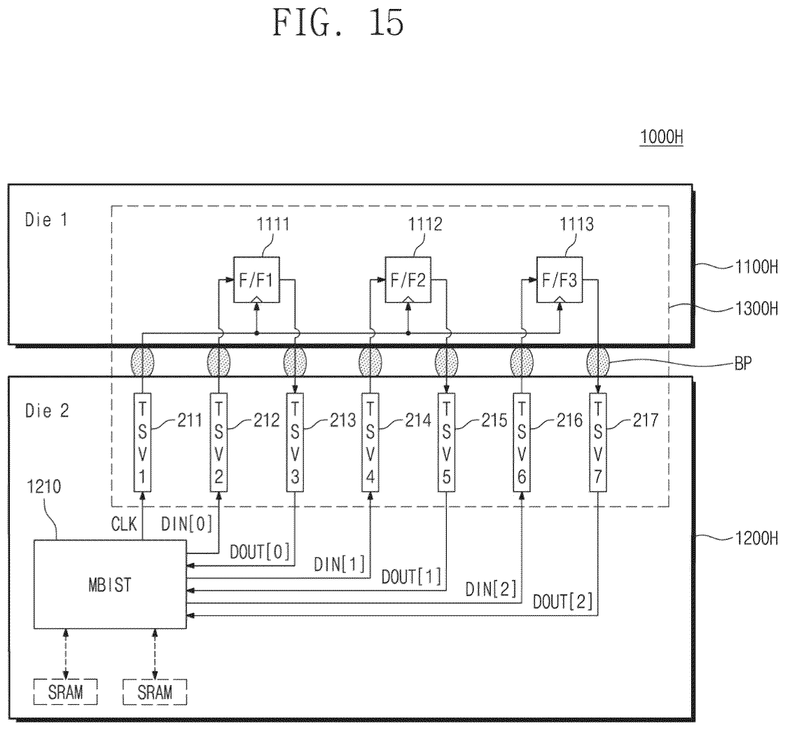

FIG. 15 is a block diagram illustrating a memory device 1000H according to an example embodiment. The memory device 1000H of FIG. 15 is similar to the memory devices 1000 and 1000A of FIGS. 1 and 2. Therefore, the same or similar components will be represented by the same or similar reference numerals, and redundant descriptions will be omitted.

In FIGS. 2 to 14, the interconnection of FIG. 1 has been described as being a through-silicon via. However, this is only an example, and example embodiments are not limited thereto.

For example, the memory device 1000H may include a first die 1100H and a second die 1200H and a bump BP may be disposed between the first die 1100H and the second die 1200H, as illustrated in FIG. 15. In this case, the interconnection of FIG. 1 may correspond to a bump. Alternatively, the interconnection of FIG. 1 may correspond to a bump and a through-silicon via. In addition, the interconnection of FIG. 1 may correspond to any medium forming a signal transmission path electrically connecting the first die 1100H and the second die 1200H. As described above, the memory device 1000H may detect a defective interconnection, among interconnections formed in various ways, without any additional overhead.

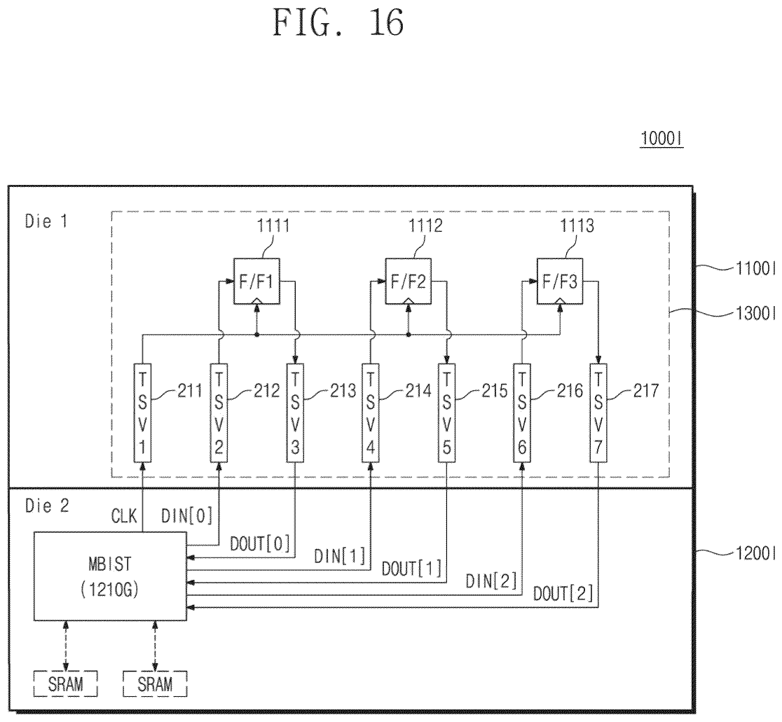

FIG. 16 is a block diagram illustrating a memory device 1000I according to an example embodiment. The memory device 1000I of FIG. 16 is similar to the memory devices 1000 and 1000A of FIGS. 1 and 2. Therefore, the same or similar components will be represented by the same or similar reference numerals, and redundant descriptions will be omitted.

In FIGS. 2 to 15, through-silicon vias has been described as being formed in a second die. However, this is only an example, and example embodiments are not limited thereto.

For example, a plurality of through-silicon vias 211 to 217 may be formed in a first die 1100I together with flip-flops 1111 to 1113, as illustrated in FIG. 16. In this case, the memory device 1000I may detect a defective through-silicon via, among a plurality of through-silicon vias 211 to 217 without any additional overhead.

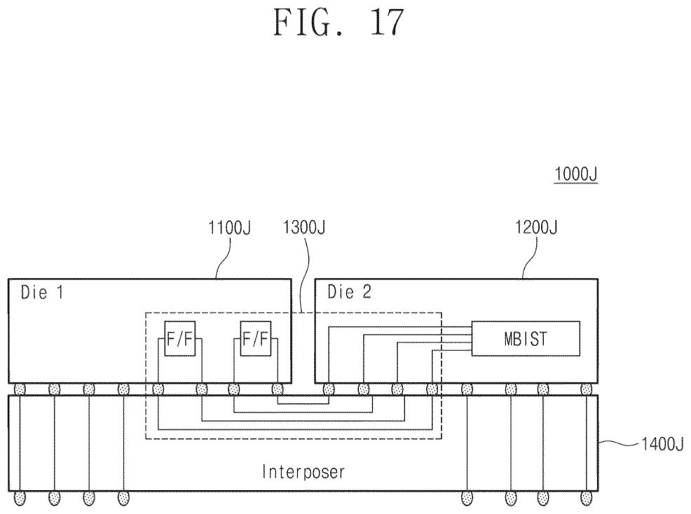

FIG. 17 is a block diagram illustrating a memory device 1000J according to an example embodiment. The memory device 1000J of FIG. 17 is similar to the memory devices 1000 and 1000A of FIGS. 1 and 2. Therefore, the same or similar components will be represented by the same or similar reference numerals, and redundant descriptions will be omitted.

In FIGS. 2 to 16, a first die and a second die have been described as being stacked in a vertical direction. However, this is only an example, and example embodiments are not limited thereto.

For example, the memory device 1000J may include a first die 1100J, a second die 1200J, and an interposer 1400J, and the first die 1100J and the second die 1200J may be disposed on the interposer 1400J, as illustrated FIG. 17. In this case, the interconnections 211 to 21n of FIG. 1 may correspond to metal lines, or the like, disposed inside the interposer 1400J. Alternatively, for example, the interconnection of FIG. 1 may be a micro-bump disposed between the first die 1100J and an interposer, or a micro-bump disposed between the second die 1200J and the interposer.

As described above, the first die 1100J and the second die 1200J may be disposed in a horizontal direction, and the memory device 1100J may detect a defective signal transmission path among signal transmission paths between the first die 1100J and the second die 1200J.

As set forth above, a memory device according to example embodiments may effectively detect a defective interconnection, among interconnections forming a signal transmission path between different dies.

While example embodiments have been shown and described above, it will be apparent to those skilled in the art that modifications and variations could be made without departing from the scope of the present inventive concept as defined by the appended claims.

What is claimed is:

1. A memory device comprising:
a first die;
a second die electrically connected to the first die;
a plurality of interconnections forming a signal transmission path between the first die and the second die;
a plurality of flip-flops provided in the first die that are electrically connected to the plurality of interconnections; and
a test circuit provided in the second die and electrically connected to the plurality of interconnections, and
wherein the test circuit is configured to perform a test operation on the plurality of interconnections using the plurality of flip-flops.

2. The memory device of claim 1, wherein the plurality of interconnections comprise first to third interconnections,
wherein the plurality of flip-flops comprise a first flip-flop electrically connected to the first to third interconnections, and
wherein the test circuit is further configured to provide a clock signal to the first flip-flop through the first interconnection, provide a data input signal to the first flip-flop through the second interconnection, and receive a data output signal from the first flip-flop through the third interconnection.

3. The memory device of claim 2, wherein the test circuit is further configured to determine whether at least one of the second interconnection and the third interconnection is defective, based on a result of comparing the data input signal and the data output signal.

4. The memory device of claim 2, wherein the test circuit is further configured to determine that at least one of the second interconnection and the third interconnection is defective, based on a value of the data input signal and a value of the data output signal being different from each other.

5. The memory device of claim 1, wherein the plurality of interconnections comprise first to fifth interconnections,
wherein the plurality of flip-flops comprise first and second flip-flops electrically connected to the first to fifth interconnections,
wherein the first and second flip-flops are configured to receive a clock signal through the first interconnection,
wherein the first flip-flop has an input terminal, selectively connected to the second interconnection or the fourth interconnection, and an output terminal connected to the third interconnection, and
wherein the second flip-flop has an input terminal, selectively connected to the second interconnection or the fourth interconnection, and an output terminal connected to the fifth interconnection.

6. The memory device of claim 5, wherein the test circuit is further configured to control the input terminal of the first flip-flop to be connected to the second interconnection and the input terminal of the second flip-flop to be connected to the fourth interconnection during a first test operation.

7. The memory device of claim 6, wherein the test circuit is further configured to control a second test operation to be performed based on at least one of the second to fourth interconnections being determined to be defective by the first test operation, and
wherein the test circuit is further configured to control the input terminal of the first flip-flop to be connected to the fourth interconnection and the input terminal of the second flip-flop to be connected to the second interconnection during the second test operation.

8. The memory device of claim 5, comprising:
a first decoding multiplexer configured to electrically connect either the second interconnection or the fourth interconnection to the input terminal of the first flip-flop; and
a second decoding multiplexer configured to electrically connect either the second interconnection or the fourth interconnection to the input terminal of the second flip-flop.

9. The memory device of claim 8, wherein the plurality of interconnections further comprise sixth to eighth interconnections,
wherein the plurality of flip-flops further comprise the third flip-flop,
wherein the third flip-flop is configured to receive the clock signal through the first interconnection, and
wherein the input terminal of the third flip-flop is connected to the sixth interconnection, and the output terminal of the third flip-flop are commonly connected to the seventh interconnection and the eighth interconnection.

10. The memory device of claim 8, wherein the plurality of interconnections further comprise sixth to eighth interconnections,
wherein the plurality of flip-flops comprise a third flip-flop,
wherein the third flip-flop is configured to receive the clock signal through the first interconnection, and
wherein the third flip-flop has an input terminal, selectively connected to the sixth interconnection or the eighth interconnection, and an output terminal connected to the seventh interconnection.

11. The memory device of claim 10, further comprising a third decoding multiplexer configured to electrically connect either the sixth interconnection or the eighth interconnection to the input terminal of the third flip-flop.

12. The memory device of claim 3, further comprising a first redundancy interconnection and a second redundancy interconnection forming a signal transmission path between the first die and the second die,
wherein the test circuit is further configured to perform a repair operation on at least one of the second and third interconnections using the first and second redundancy interconnections based on determining at least one of the second and third interconnections is defective.

13. The memory device of claim 12, wherein the plurality of interconnections further comprise fourth to seventh interconnections,
wherein the plurality of flip-flops further comprise a second flip-flop and a third flip-flop electrically connected to the fourth to seventh interconnections,
wherein each of the second and third flip-flops is configured to receive the clock signal through the first interconnection,
wherein the first flip-flop has an input terminal, selectively connected to the second interconnection or the fourth interconnection, and an output terminal selectively connected to the third interconnection or the fifth interconnection,
wherein the second flip-flop has an input terminal, selectively connected to the fourth interconnection or the sixth interconnection, and an output terminal selectively connected to the fifth interconnection or the seventh interconnection, and
wherein the third flip-flop has an input terminal, selectively connected to the sixth interconnection or the first redundancy interconnection, and an output terminal selectively connected to the seventh interconnection or the second redundancy interconnection.

14. The memory device of claim 13, comprising:
a first shift multiplexer configured to electrically connect either the second interconnection or the fourth interconnection to the input terminal of the first flip-flop;
a second shift multiplexer configured to electrically connect either the fourth interconnection or the sixth interconnection to the input terminal of the second flip-flop;
a third shift multiplexer configured to electrically connect either the sixth interconnection or the first redundancy interconnection to the input terminal of the third flip-flop;
a fourth shift multiplexer configured to electrically connect either the output terminal of the first flip-flop or the output terminal of the second flip-flop to the fifth interconnection; and
a fifth shift multiplexer configured to electrically connect either the output terminal of the second flip-flop or the output terminal of the third flip-flop to the seventh interconnection.

15. The memory device of claim 14, further comprising:
a sixth shift multiplexer configured to receive a first data input signal and a second data input signal from the test circuit and transmit either a first test input signal or a second test input signal to the fourth interconnection;
a seventh shift multiplexer configured to receive the second data input signal and a third data input signal from the test circuit and transmit either the second test input signal or a third test input signal to the sixth interconnection;
an eighth decoding multiplexer configured to electrically connect either the third interconnection or the fifth interconnection to the test circuit and transmit a first data output signal to the test circuit;
a ninth decoding multiplexer configured to electrically connect either the fifth or seventh interconnection to the test circuit and transmit a second data output signal to the test circuit; and
a tenth decoding multiplexer configure to electrically connect either the seventh interconnection or the second redundancy interconnection to the test circuit and transmit a third data output signal to the test circuit.

16. The memory device of claim 1, wherein each of the plurality of interconnections is a through-silicon via.

17. The memory device of claim 1, wherein the plurality of interconnections are disposed on either the first die or the second die.

18. The memory device of claim 1, further comprising an interposer comprising the first die, the second die, and the plurality of interconnections.

19. A memory device comprising:
a first die;
a second die;
a plurality of through-silicon vias extending through the second die and forming a signal transmission path to the first die; and
a plurality of flip-flops provided in the first due that are electrically connected to the plurality of through-silicon vias;
a test circuit provided in the second die and electrically connected to the plurality of through-silicon vias,
wherein the test circuit is configured to detect whether the plurality of through-silicon vias are defective, using the plurality of flip-flops.

20. A memory device comprising:
an interposer;
a first die on the interposer;
a second die on the interposer and spaced apart from the first die along a horizontal direction;
a plurality of interconnections in the interposer forming a signal transmission path between the first die and the second die;
a plurality of flip-flops in the first die electrically connected to the plurality of interconnections; and
a test circuit in the second die electrically connected to the plurality of interconnections,
wherein the test circuit is configured to detect whether plurality of interconnections are defective, using the plurality of flip-flops.
